(19) United States
(12) Patent Application Publication
(10) Pub. No.: US 2010/0212719 A1
(43) Pub. Date: Aug. 26, 2010

(54) SYSTEM AND METHODS OF UTILIZING SOLAR ENERGY

(76) Inventor: Hans-Henrik Kofoed Stolum, Cambridge (GB)

Correspondence Address: REMENICK PLLC, 1025 THOMAS JEFFERSON STREET, NW, WASHINGTON, DC, 20007, US

(21) Appl. No.: 12/666,431

(22) PCT Filed: Jun. 25, 2008
(86) PCT No.: PCT/GB08/02239

§ 371 Date: May 5, 2010

Related U.S. Application Data
(60) Provisional application No. 60/946,138, filed on Jun. 25, 2007.

(51) Int. Cl. H01L 31/052; F24J 2/10; F24J 2/34

(52) U.S. Cl. 136/246; 126/684; 126/617

(57) ABSTRACT

A system and methods for utilizing solar energy is proposed. The invention consists of: (i) A sunlight concentrator that is either panel-shaped or take the form of separate containers, either of which allow at least 45 degrees light incidence angle deviation from the orthogonal, and therefore does not require a tracking device. Said panel is planar, or has a gentle curvature, but is of fixed shape. Said concentrator has two embodiments, one of which is based on a plurality of light-tubes, the other is based on a plurality of mirrors. (ii) Methods of energy conversion to electricity, embodied in a concentrator exit structure combined with a spatial arrangement of photovoltaic cells. (iii) Methods for conversion of solar radiation to heat, embodied in a concentrator exit structure combined with a heat energy storage unit built according to principles set forth herein. (iv) Methods of dual land use of a concentrator field and of conversion to electricity from an area covered with water, by the use of adapted support structures.

### BACKGROUND OF THE INVENTION

The invention relates to conversion of solar radiation into useful forms of energy (electricity or heat). Specifically it relates to sunlight concentrators that can be used as passive light collectors (that do not need active tracking of the sun), that take the form of flat or gently curved concentrator panels or fields, and allow a high concentration factor in the range of 5-1300. The invention further relates to heat storage systems that allow the sunlight to be used overnight for solar concentrator plants, and systems that allow a concentrator field to be located at sea or on a lake, or suspended above ground using a light support structure. Finally the invention relates to methods for increasing the photovoltaic conversion factor possible with any given photovoltaic conversion medium, such as CIGS thin films and silicon cells.

Relative to a panel that covers the whole incidence area with photovoltaic cells or a photovoltaic thin film, the purpose of using a concentrator is to reduce the component cost of the photovoltaic material without adding the expense of a tracking device. The invention reduces the photovoltaic area with a factor that can be scaled to between 1/5 and 1/7000 of the panel area, with preferred embodiments in the range of 1/10 to 1/1300. Because the concentrator itself relies only on simple production methods and inexpensive materials, it can be produced at a reduced cost per area unit relative to covering the same area with a photovoltaic material of the same conversion efficiency.

Current flat-panel concentrators have limited usefulness because they require the panel surface to stay orthogonal to the sun in order to work. They must therefore be mounted on active tracking systems (heliostats). The invention overcomes this limitation, and efficiently utilizes sunlight at incidence angles of at least 45 degrees. This property further allows surface reflectance losses to be efficiently constrained using either a single axis tracking device or no tracking device.

There are currently no solar thermal power plants that do not require active tracking. Current heat storage systems are subject to substantial heat loss due to the simplicity of their construction, which typically takes the form of a hot core of a latent heat medium surrounded by an insulating layer, or a core of sufficiently low thermal conductivity that it does not require insulation (e.g. graphite, concrete).

U.S. Pat. No. 4,440,153 and U.S. Pat. App. 20060274439 both describe concentrators based on filled, parabolic mirrors that require active tracking. U.S. Pat. App. 20060274439 teaches a flat panel modular concentrator based on a plurality of parabolic filled mirrors and the use of a Cassegrain two-mirror arrangement for tracking-based solar concentration. These patents are outside the scope of the present invention, which does not extend to neither imaging optical systems nor parabolic mirrors that require tracking.

U.S. Pat. No. 6,700,054, Int. Pat. No. WO 00/07055, and U.S. Pat. App. 20050081909 all describe a solar concentrator in the form of a tapered lightguide. U.S. Pat. App. 20050081909 teaches a flat panel modular static concentrator based on a plurality of conical or parabolic mirrors. This patent application is outside the scope of the present invention because when construed as short tapering light tubes, said conical or parabolic mirrors are not curved or curvilinear as taught herein, but strictly linear, and the concentration factor is ×3, and thus outside the range that defines the present invention. When construed as deep parabolic mirrors, the patent application remains outside the scope of the present invention since the system described herein does not extend to parabolic or conical mirrors.

U.S. Pat. No. 6,994,082 and U.S. Pat. App. 20080047546 teach an inflatable balloon formed from one clear and one reflecting film, such that either an oblate, spherical form or a parabolic form results, capable of concentrating light onto an internal PV cell. The method requires active tracking. While being a container embodiment of a mirror concentrator, the patent application is outside the scope of the present invention because the oblate ellipsoid is substantially and functionally different from the ellipsoidal shape described herein, and because said patent application does not specify or include any method of giving the balloon the shape described by the present invention. While said patent application claims a solar concentrator in the form of a balloon in general, the present invention describes a solar concentrator in the form of a closed container, of which a balloon is an embodiment. Thus the use of a balloon as a preferred embodiment of the present invention does not constitute an infringement of said patent application. Said patent teaches a combination of inflation and tensile support fibers that give the balloon a parabolic shape, but the tensegrity method described in the present invention does not rely on inflation, and the present invention does not extend to parabolic mirrors.

U.S. Pat. No. 6,274,860, U.S. Pat. No. 6,958,868, and U.S. Pat. App. 20070107770 describe flat panel static concentrators based on holographic principles. In the case of U.S. Pat. No. 6,274,860 the method is capable of reaching a concentration factor of ×6. Said concentrator panels have substantially similar properties to the panel concentrator described herein, but the use of holographic methods is outside the scope of the present invention.

JP Pat. No. 2005123036 describes a planar, modular static mirror concentrator. While the panel has many of the same properties as the concentrator panel described herein, said patent employs a very different mirror shape that functions substantially differently from the present invention.

### SUMMARY OF THE INVENTION

The invention is a system for utilizing solar energy, consisting of a solar energy concentrator, which concentrates and transports sunlight, combined with either a heat storage system or a photovoltaic electricity conversion system. The heat storage system may for instance be used to drive a steam-based turbine continuously overnight in a solar thermal power plant.

The basic element of the system is a flat concentrator panel or field that allows a low light incidence angle and therefore does not require a tracking device. The panel may be planar, or have a gentle curvature. The system may for example be applied in the form of roof tiles, vehicle surfaces, solar panels floating in the sea or on lakes, or a field of solar thermal concentrators.

The concentrator has two embodiments, a light tube system and a mirror system. The mirror concentrator panel consists of round or trough-shaped mirrors with a co-adapted photovoltaic or thermal converter located at their center. The light tube concentrator panel is modular, and based on a hierarchical arrangement of curved tubes that transport light either to a photovoltaic converter, or to a heat storage unit.

The heat storage method is a method for extenuating heat loss from a hot core. An insulating container is multilayered such that an inner zone acts as a secondary heat storage zone that supplies heat to the hot core during extraction of energy.

The invention includes a PV concentrator field capable of being positioned above ground and therefore allowing dual use of the land area, and a PV concentrator field capable of floating in the sea or on a lake.

### BRIEF DESCRIPTION OF THE DRAWINGS

FIG. 1 shows two light tube concentrator modules with different concentration factors, viewed from above and the side. Example a concentrates light to ×12, and example b to ×30.

FIG. 2 illustrates ray trajectories through curved entry tubes Example a has a curvature radius of 4 and a lensoidal surface layer. Example b has a planar surface layer in optical continuity and tapering light tubes. This embodiment concentrates light to ×5.5.

FIG. 3 is a circular light control tube and entry tubes viewed from above and the side.

FIG. 4 is a circular light control tube and entry tubes viewed from above. The ray trajectories from a single entry tube show the emergence of light spots (arrows).

FIG. 5 is a concentrator unit of five control tubes connecting to a curved exit tube, and a modular round concentrator in which a plurality of concentrator units terminate at the center, for example in a heat storage unit.

FIG. 6 is a concentrator field in which a plurality of equal-sized modular round concentrators (e.g. higher-order modularized versions of the arrangement shown in FIG. 4) are connected via curved exit tubes to two linear heat storage unit heat storage units that connect via steam pipes to a centrally positioned turbine. Concentration factor ×100.

FIG. 7 depicts a gently curved concentrator panel of filled light tubes in side view. The panel casing has a reflective interior surface with ridges.

FIG. 8 depicts various embodiments of the plural mirror concentrator in vertical cross section. a. hollow mirror with lensoidal surface layer. b. hollow mirror with Fresnel surface layer, leading to light tubes such as in FIG. 2b and FIG. 14, mounted in heat pipes. Concentration factor ×700. c. filled mirror with planar, optically continuous surface layer. d. filled mirror with lensoidal, optically continuous surface layer.

FIG. 9 depicts self-contained singular mirror concentrator units with a rod-shaped converter. Example a has a uniform planar surface layer, and concentration factor ×14. Example b has a lid with lensoidal properties, which increases concentration factor to ×21.

FIG. 10 depicts an inflatable embodiment of the self-contained singular mirror concentrator. a. reflector film with incisions. b. concentrator inflated.

FIG. 11 is a tensegrity structure designed to support a self-contained concentrator unit. a. ribcage structure and ring. b. concentrator unit.

FIG. 12 depicts two-mirror concentrator units with planar and lensoidal surface layers. Example a has concentration factor ×36, example b ×225. Example b further shows elimination of chromatic aberration by ray tracing, and two trough concentrators mounted on a single axis tracking device.

FIG. 13 are cross sections of trough-shaped mirror concentrators. Example a depicts a one-mirror embodiment with ×25 concentration. Example b shows a two mirror embodiment with ×225 concentration, and a single axis solar-driven tracking device based on solar-adjustable fluid-filled weights.

FIG. 14 shows examples of low-angle positioning of PV cells relative to ray trajectories in curved and curvilinear light tubes.

FIG. 15 is a cross section through a photovoltaic cell. The two bars to the left of the figure show the different conversion conditions when the light enters at an angle relative to orthogonal to the PV surface.

FIG. 16 depicts three embodiments of the PV converter: a. flat singular converters with and without a secondary mirror attached. b. Two rod-shaped singular converters. c. Plural converter with 8 elements.

### DETAILED DESCRIPTION OF THE INVENTION

Systems and methods in accordance with various embodiments of the present invention can overcome the aforementioned and other deficiencies in existing photovoltaic and solar thermal systems and devices, by changing the way in which light is collected and directed towards the photovoltaic and heat storage elements, as well as changing and controlling the interaction between the light and photovoltaic elements, and changing the way in which heat is lost from heat storage units.

Said systems do this by having the following properties imparted by the methods of the invention (claim 1):

The concentrator has high tolerance to light incidence angle down to 45 degrees, and thus there is no critical need for an expensive tracking device or other moving parts. This property also allows the system to function under diffuse light. Preferred embodiments of the system include a static system, and the use of a simple one-axis tracking system for the purpose of reducing reflective surface loss.

The concentrator is an efficient light collector, in that it takes the form of a flat, or very gently curved panel, which means that all elements on it receives the same amount of light and hence all are fully active at any time.

The concentrator works optimally in the concentration range of 6-30 times. It can also be made to deliver a very high concentration factor. For example, the mirror embodiment will still function efficiently at 300 times concentration. The light tube embodiment will still function efficiently at 50 times concentration.

The concentrator can be made from inexpensive materials, using inexpensive mass production processes such as injection molding. On the other hand, by using more expensive high quality reflective coatings or transparent materials of high transmissivity, significant improvements of internal light loss can be achieved. Thus there is a direct trade-off between cost and the main efficiency bottleneck of the system. If there is only moderate limitation on the area available, the concentrator can be very low cost per square meter, while if it is strictly limited to, say, the area of a car roof and has to be made very thin, the embodiment can be made more efficient, but also more expensive. The system can therefore be adapted to a range of conditions, and optimized for efficient cost control under any given constrains.

The electricity converter will consistently deliver a high conversion ratio due to a high degree of control over the exit light incidence angle onto the photovoltaic cell surface. The ratio is higher than obtainable by covering the whole panel surface with the same photovoltaic material. The largest relative gain will be achieved if CIGS or other thin film materials are used, and for a concentration factor in the range of 6-30, which minimizes internal light loss, avoids heat problems, while remaining highly cost-effective in terms of use of photovoltaic materials.

The heat converter is capable of storing sufficient heat energy for continuous overnight use, provided it is scaled to the capacity required. It works by having a secondary heat storage zone with low thermal conductivity in contact with a hot core that supplies heat for external use.

The present invention is described more fully hereinafter with reference to accompanying drawings, in which preferred embodiments of the invention are shown. This invention may, however, be embodied in many different forms and should not be construed as limited to the embodiments set forth herein; rather these embodiments are provided so that this disclosure will be thorough and complete, and will fully convey the scope of the invention to those skilled in the art. Like numbers refer to like elements throughout.

### The Light Tube Concentrator Panel

In one of the preferred embodiments of the present invention, the concentrator takes the form of an assemblage of light tubes. It is known to those in the art that a light tube embodies a method for directional transport of light. Light enters at one end and exits at the other, and hence light tubes are transparent at both ends and internally. Light tubes are either hollow or filled. If hollow, they are covered or coated on the inside with a high-reflectance material, and light transport occurs by wall reflection. If filled, they do not have walls, but are made from a highly transparent material such as glass (e.g. water-white glass or acrylic) and transport light by the well-known principle of total internal reflection below a critical angle

The use of filled tubes is a preferred embodiment where the panel needs to be thin, such as in a concentrator panel covering an automobile roof. In this case each tube has to be small, and wall thickness can therefore be a substantial source of inefficiency. Where there is no constraint on the thickness of the panel and the objective is to cover a very large area and minimize light loss over large transport distances, hollow tubes are the less expensive option and therefore a preferred embodiment.

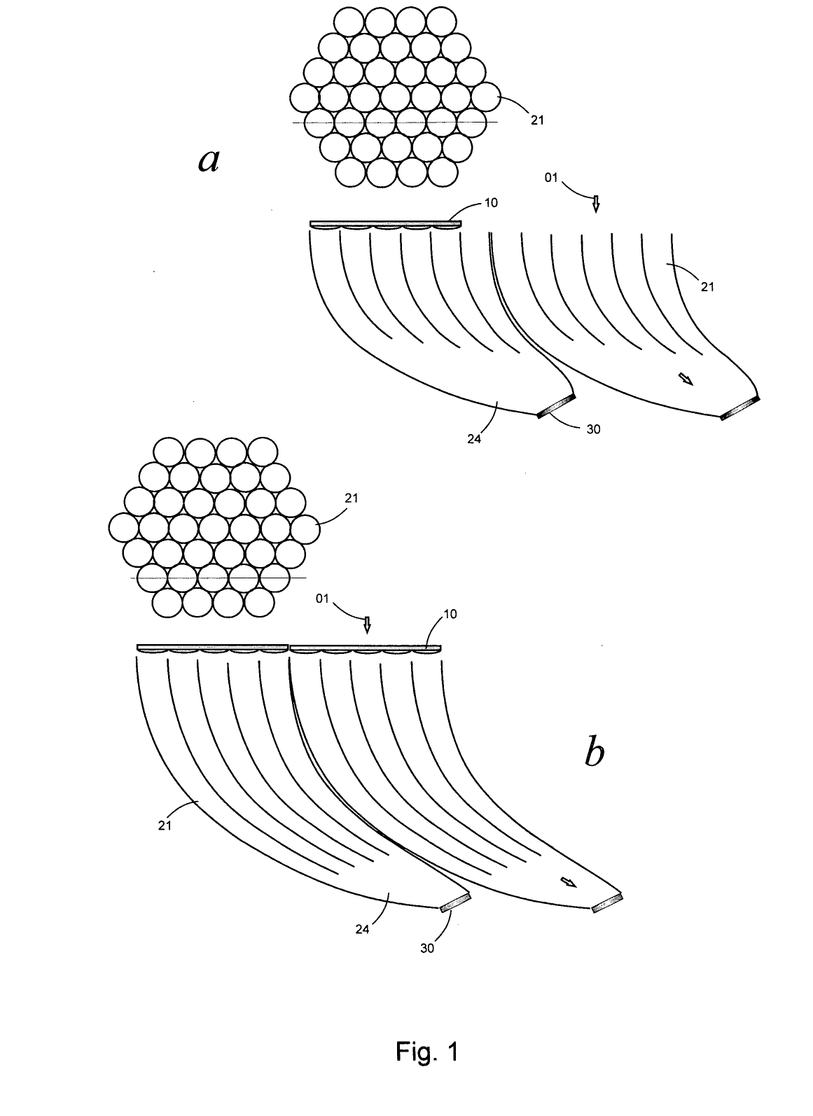

In all FIGS. 1-7, a light tube concentrator consists of the following elements: A surface or surface layer 10 which may include a lensoidal underside is located above a branching light tube structure 20 that leads to a converter unit 30, all of which is encased in a protective casing 40. The entry tubes 21 lead into either a curvilinear or linear transport tube 22 or a light control tube 23 that terminate in a single curvilinear or linear exit tube 24, which may have a separate diffuser section 25. Open arrows 01 show the direction of light into and out of the system, while filled arrows 02 terminate ray trajectories through the system according to Snell's law. Ray trajectory 020 denotes incident light that enters the system at a 90 degrees angle (orthogonal) to the surface layer, and 021 denotes incident light that enters at a 45 degrees angle. The structures shown in FIG. 1-7 are identical in respect to the hollow and filled embodiments, and apply equally to both.

The basic arrangement of light transport tubes described in claim 2 is termed a singular concentrator unit. The unit is defined by having a single light exit point, which may terminate either within the unit in an inbuilt energy converter, such as a photovoltaic cell, or connect to an external heat exchange unit via a single exit tube.

FIG. 1 describes embodiments of singular concentrator units with concentration factor ×12 (FIG. 1a), and ×30 (FIG. 1b). Open arrows 01 show the direction of sunlight into the system. A surface layer with a lensoidal underside 10 is located above a branching light tube structure 20. A plurality of entry tubes 21 lead into a single tapering curvilinear diffuser exit tube 24. The exit tube leads, to a converter 30, in the form of a singular photovoltaic element.

The tube arrangements of FIG. 1 may for example be manufactured using injection molding of acrylic resin to provide a filled tube system. Likewise they may for example be manufactured as a hollow tube system by separate plastic forming (e.g. injection molding) of an upper section containing the entry tubes and a lower section containing the exit tubes. Each part is then vacuum coated with aluminium for reflectivity and joined together.

Alternatively, the exit tube may be a hollow diffuser, and the entry tubes manufactured as a set of hollow tubes or acrylic rods that are heated and drawn for tapering and curvature such as for example shown in FIG. 1b. The tube set is then fitted into the opening of the diffuser at the tapering end.

The invention includes several methods for reducing internal light loss within the concentrator while maintaining a high concentration factor. The attainable efficiency and concentration factor is limited by total travel distance of the light because of refractive light loss at the tube walls of hollow tubes or loss due to imperfect transmissivity of any filled tube material.

Claim 2 discloses a method of reducing light loss within a hollow tube concentrator by increasing tube diameter between entry and exit point for the light, and thus decrease the number of reflection points. For a filled tube concentrator increasing tube diameter likewise allows maintaining a constant optimal light flux density throughout the concentrator.

Claim 3 discloses a method of reducing light loss within the concentrator. A modular concentrator unit is defined as comprising a plurality of singular concentrators with their converters connected in series or parallel. They terminate in one or more external exit points for the resulting electric current generated within the modular concentrator panel. This arrangement gives a lower concentration factor than a singular unit of the same area, but also reduces light loss since the mean light travel distance is reduced. The use of a modular arrangement thus gives control over several parameters of the concentrator panel, and allows precise optimization for specific uses.

FIG. 1 describes embodiments of a modular concentrator in which each singular unit can be tightly packed within the concentrator panel frame. Said units may be produced individually, and then fitted or slotted into the casing of the final panel and connected in series or parallel. This can be done using an automated method, thus allowing a wide range of panel or tile shapes and sizes to be easily mass produced within the same production cycle.

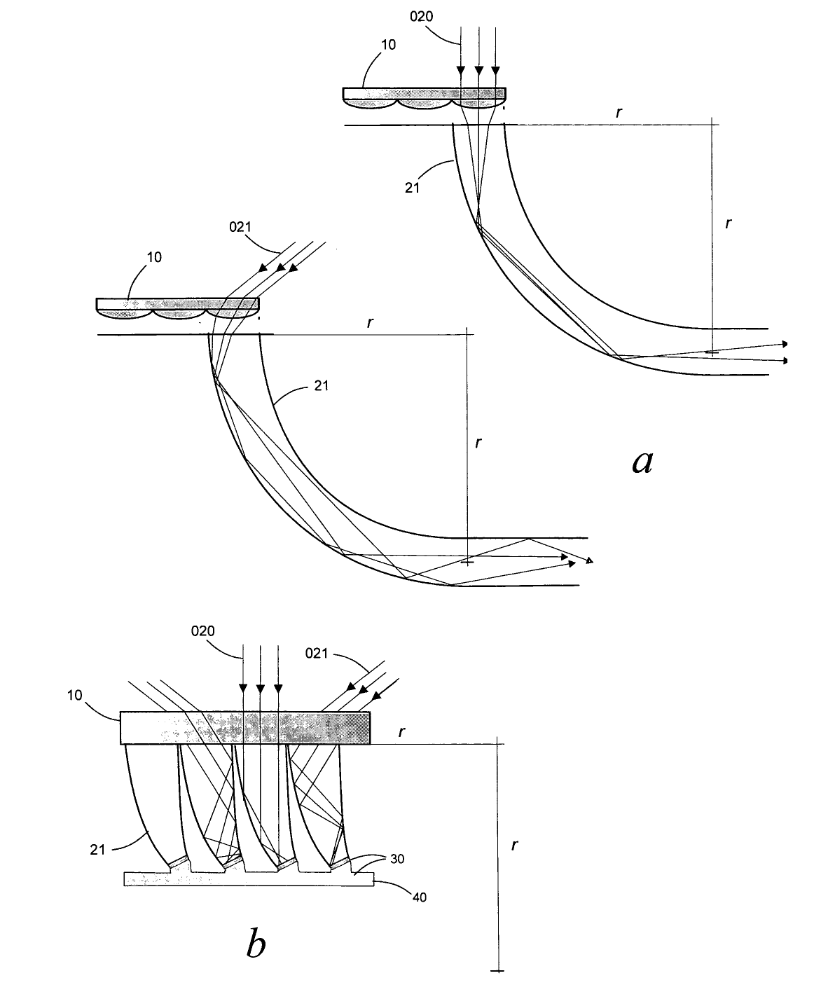

Claim 4 discloses a method of simultaneously reducing light loss and chromatic aberration within the concentrator. It refers to the observation, in accordance with Snell's law, that there is less light loss within the curved section relative to the light loss of a straight tube between the end points of the same diameter (from either wall refraction or transmissivity loss) if the dimensionless curvature (normalized by tube diameter) has a value of 4 or larger (FIG. 2). Losses rise sharply below a curvature value of 3.7, and at curvatures of 3 or less, approximately 50% of the light is dissipated within any single bend.

Claim 4 further refers to the observation that said principle can be used as s method for keeping light incidence angles consistently below the critical angle of total internal reflection, which for glass and acrylic is approximately 48 degrees measured from the tube wall (FIG. 2). Thus light tube concentrator embodiments according to the present invention use mostly or only tubes that are curved or curvilinear, such that all tube curvatures have a value of at least 3.7, and generally >=4.

The use of an initial lens introduces chromatic aberration, a refraction phenomenon known to reduce the efficiency of photovoltaic cells. Claim 4 further refers to the observation, in accordance with Snell's law, that the use of a curved entry tube section or any curved or curvilinear tube section according to the principle disclosed in claim 4, acts to eliminate or minimize chromatic aberration by random chromatic re-mixing and re-focusing (FIG. 2). Any light tube concentrator in accordance with claim 4 therefore further acts a method and apparatus for this purpose.

In a preferred embodiment, a modest degree of tube tapering, e.g. with linear, parabolic, elliptic or catenary tapering curvature, is used as a final concentrating step of the exit tube (FIG. 1). It is known in the art that light concentration via tapering of a straight light tube rapidly leads to significant refraction and transmissivity losses. However, when the light entering said linear tapering section has a deviation angle from the section centerline of no more than 45 degrees, and the concentration within the tapering section is increased with no more than a factor of ×3, all light trajectories will reach the converter. Furthermore, in the case of a filled tube it is possible to maintain total internal reflection under said conditions.

If the tapering section further is curved according the principle of claim 4, it is possible to increase the concentration factor to at least 5.5 without increasing light losses using a planar surface layer (FIG. 2b). It is further possible in said arrangement to replace the planar layer with a lensoidal surface layer and thus further increase the concentration factor to 6.5 or more without increasing losses. A simplest possible concentrator structure wherein each entry tube is also an exit tube and where each tube is curved or coiled within a 90 degree arc according to claim 4 is therefore a preferred embodiment of the concentrator (FIG. 2b). Said concentrator may be manufactured in a single manufacturing step by injection molding of acrylic resin or glass, and using a mold with a slider component. At small tube scale the concentrator may also be produced in the form of a thin plastic sheet or film, whereupon the converter units for example are deposited using an inkjet method. The converter units and their connection grid may be positioned on the concentrator, or on the surface of a separate layer, such as a protective back panel (FIG. 2b). Said panel or layer may further be transparent and the gap between the concentrator sheet and back panel sheet may be evacuated for insulation purposes.

It is further possible to orient the entry tubes at another angle to the surface layer than orthogonal. In a preferred embodiment of the invention the entry tubes are oriented 45 degrees to the surface layer. This arrangement is used if the concentrator is positioned vertically, as a wall panel or tile.

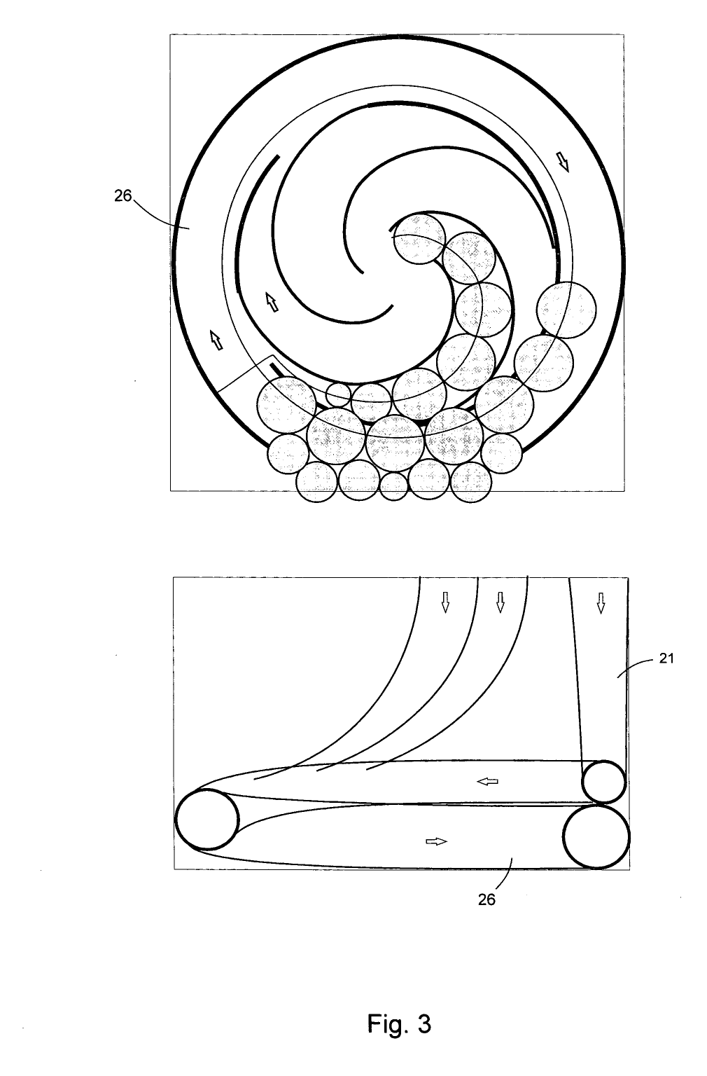

A tube connection method is disclosed in claim 5 and shown in FIG. 1 and FIG. 3. If the smaller tubes connect to an expanding tube using a parallel lead-in section in the manner described herein, light loss at connection points is eliminated, albeit at the cost of reducing the concentration factor. This spatial arrangement is a therefore a preferred embodiment of tube connections according to the present invention. However sub-parallel connections with a divergence angle of up to 25 degrees may not result in significant light loss if the distance from the connection lead-in to the converter is short, or if the larger tube is a light control tube (26) as described in claim 5(ii) (FIG. 3).

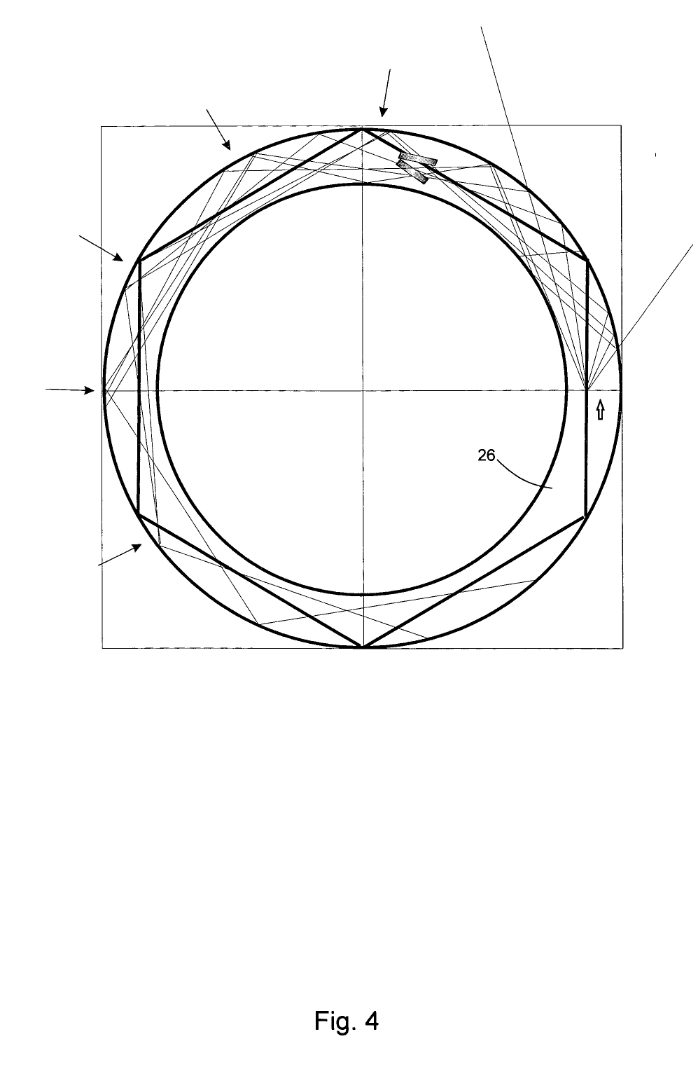

The light control tube controls the light flux by causing ray trajectories to become more parallel and their reflection points to converge on regularly spaced light spots within the tube (FIG. 4). In one preferred embodiment the light control tube connects to, or opens into an exit tube of the kind described in claim 5(i). Said connection is positioned such that ray trajectories reflected from a light spot extend into the exit tube close to the exit tube centerline. This arrangement reduces the number of reflection points and thus light loss throughout the exit tube (claim 5iii).

In general, the larger the diameter of the tubes, the less reflective and refractive contact the light will have with the tube wall (i.e. the more of the distance traveled by ray trajectories is spent within the tube medium) for any given tube length. Light loss reduction is therefore achieved when the light flux cross-sectional area in the system is increased, by increasing either the total or the average tube cross-sectional area of the hollow tube embodiment (claim 2, 5).

If panel thickness is not a major constraint, using tubes with a large diameter therefore allow the furthest light transport for the least amount of relative light loss. In a typical embodiment of this form, hollow tubes with a reflective internal coating further allow very large panels to be relatively lightweight and made from inexpensive materials. Hence a hollow tube arrangement is the preferred embodiment of the invention for delivering energy to a solar thermal power plant.

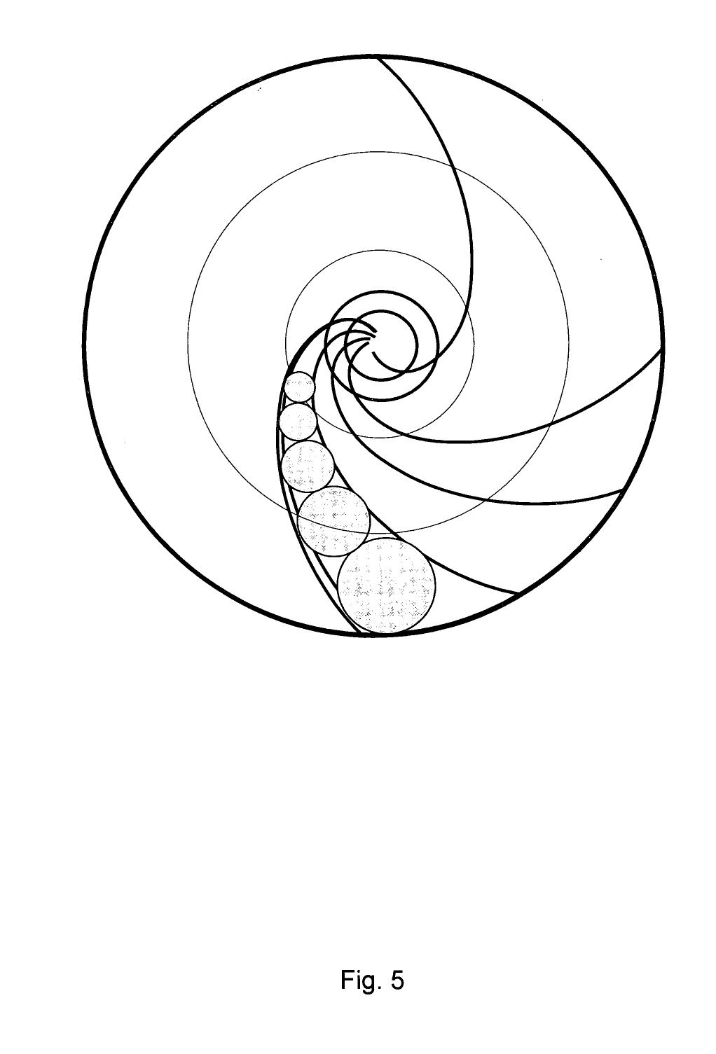

In one such preferred embodiment, light is first transported from entry tubes into a light control tube and from there into an exit tube of the kind described in claim 5(i). Said exit tube then terminates in a heat distributor. A plurality of light control tubes connect to a single exit tube, and this arrangement forms a singular concentrator unit (FIG. 5) within a modular concentrator, wherein said units are arranged radially in a circle around the heat storage unit such that the light flux direction of the concentrator is central.

In a preferred embodiment of said power plant, the turbine is located between a plurality of concentrators, with an arrangement of pipes transporting a hot fluid, such as steam, from a plurality of heat storage units (60) to the turbine (70).

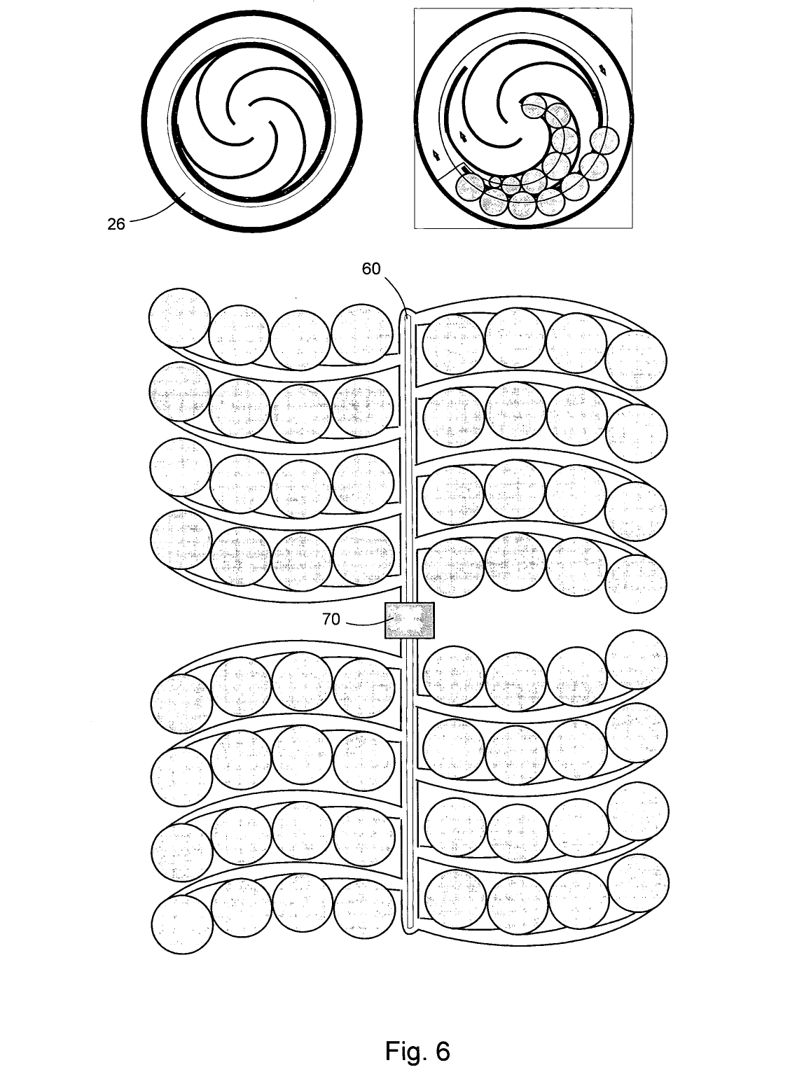

The direction of light flux within each concentrator may be either radial or central, as shown in FIGS. 5 and 6. If the concentrator has a peripheral light control tube that connects to an exit tube spanning several concentrators the scaling range of light flux transport can be extended. In this embodiment the system described in claim 2 takes the form of a prefractal scaling hierarchy of concentrator units connecting to form a larger-scale concentrator.

In one preferred hollow tube embodiment each element that consists of entry tubes leading into one light control tube is made from extruded blocks of an embedding material. The blocks act as molds that slot into each other, such that the hollow interior structure of the concentrator results when the blocks are fitted together. The embedding material may for example be a rigid foam such as expanded polystyrene or PUR.

In a preferred hollow tube embodiment the reflective surface is made up of a plurality of flexible aluminized plastic sheets. Said sheets may be small relative to the wall curvature, and made from an inexpensive reflective material such as for example an aluminized plastic film (e.g. Mylar), or a laminate that is flexible but not crease-prone. Such a laminate can for example have an aluminized plastic film surface layer, or a dielectric mirror coated surface, and a further aluminized plastic sheet (e.g. Heat Shield) underneath. It is possible that that said laminate requires the use of plastic materials with an unusually high melting point. These flexible tiles are placed in a tiling arrangement, and affixed for example with Velcro, or fitted at the corners into slits in screws with a reflective head, protruding from the surface of the embedding material. To further improve reflectivity, for example in the infrared range, a plurality of flexible tiles with different reflectance properties can be stacked.

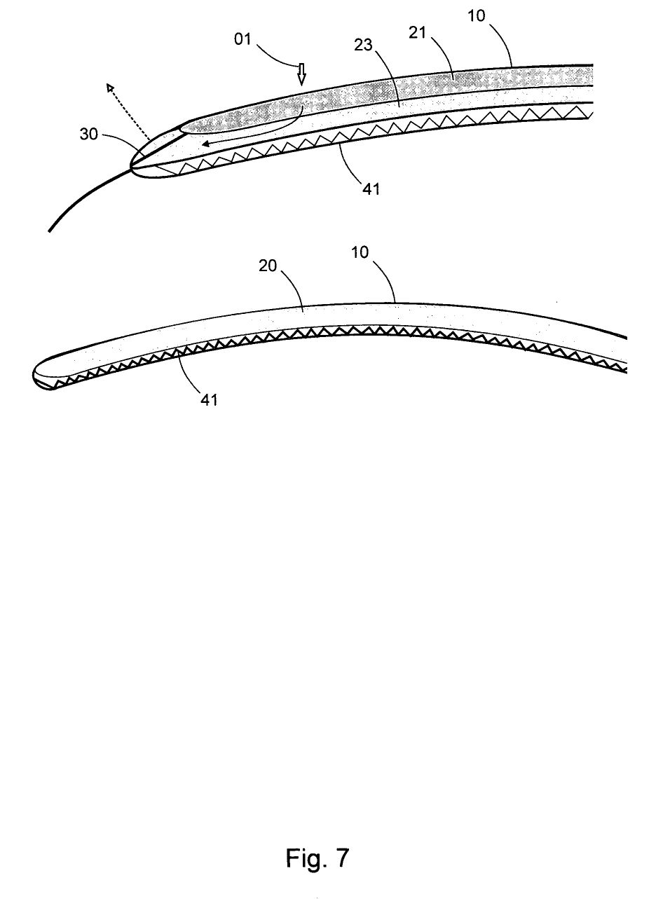

Light may escape from a system based on total internal reflection because the reflection is only total when the light reflects below the critical angle. Refracted light can re-enter the concentrator if it is reflected from the bottom and sides of the panel casing (claim 5(iv)). The system will achieve this most efficiently if the bottom consists of ridges orthogonal to the direction of light movement with side angles of 45 degrees (41) (FIG. 7). This allows refracted light back into the tubes, albeit with reduced transport efficiency. Hence in a preferred embodiment the inside of the panel casing is coated with a high-reflective material to this effect.

It is known in the art that refracted light can also be used for passive heating or cooling of a surface, in this case the surface underneath the panel. Said internal casing reflection increases the amount of solar energy that is prevented from reaching the surface below. This is particularly effective for passive cooling if the reflective material is capable of reflecting infrared light, such as an aluminized plastic sheet or film (e.g. Mylar and Heat Shield), or a combination of said materials. Conversely, if instead a heating function were to be desirable, the casing can easily be manufactured as a heat sink by being made from, or incorporating an element of a heat-absorbing material, and having a dark, non-reflective inner surface. Secondary far-infrared emittance from this material will be unable to escape through the concentrator, and hence heat is efficiently trapped in the casing, from where it will transmit to the surface beneath the panel. This allows the panel to have a dual use, e.g. generation of electricity as primary function and heating of water or passive cooling as a secondary function.

### The Mirror Concentrator Panel

A light concentrator may the form of a singular or a plurality of concave elliptical, catenary or cycloidal mirrors, each forming a light attractor basin by reflection. These basins take the form of concentrator units that are either round or trough-shaped in outline (claim 8). A round concentrator unit is preferably circular in plan view, but may also consist of a plurality of sector-shaped segments at an angle to each other. A single concentrator unit, or a plurality of said units interlinked or placed within an external support structure such that they form a flat or gently curved panel with the properties stated in claim 1, are referred to as the mirror embodiment of the concentrator.

Hereafter the case of a plurality of mirrors formed from a single sheet (claim 9i and 9ii) is referred to as a “plural mirror”, and the case of a single self-contained mirror (claim 9iii) is referred to as a “singular mirror”. Said mirror shapes may be produced as concave hollows (hereafter referred to as “hollow mirrors”) by a process such as vacuum or injection molding of a plastic sheet, followed by coating with a high-reflective material. Alternatively, the mirror cavities may be produced as convex protusions of one surface of a sheet (hereafter referred to as “filled mirrors”). In the case of filled mirrors, the method of reflection is total internal reflection and the sheet must therefore be transparent. It can for example be made from acrylic resin using injection molding. A filled mirror can also be made from glass (e.g. white water glass), using a glass molding method. With small scale protusions the plural concentrator may further be produced by thermoforming of a thin plastic sheet or film, whereupon the converter units for example are deposited using an inkjet method. Alternatively, the converter units and the grid that connects them may be positioned on the surface of a separate layer or back panel. Said panel or layer may further be transparent and the gap between the concentrator sheet and back panel sheet may be evacuated for insulation purposes.

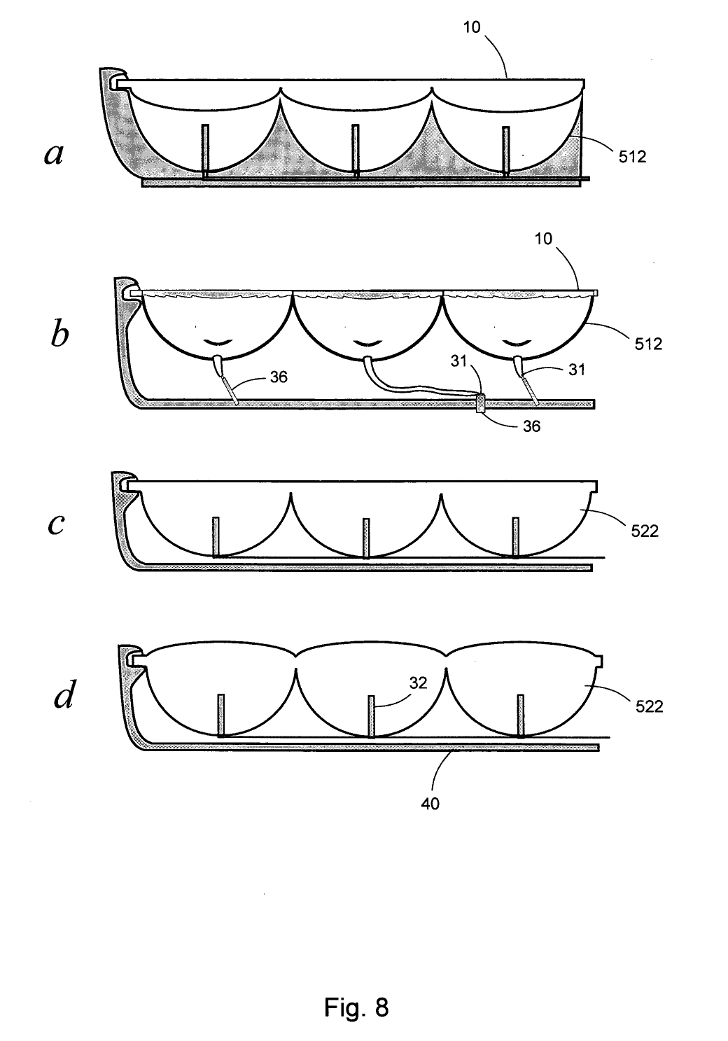

FIGS. 8-13 describe embodiments of the mirror concentrator that include some or all of the following elements: A surface layer 10, which may include a lensoidal underside, is located above a mirror forming a reflector basin 50, which may be either a singular mirror 51, or a sheet formed into a plural mirror 52. Either instance may be a hollow singular mirror 511, a hollow plural mirror 512, a filled singular mirror 521 or a filled plural mirror 522. In addition the concentrator may include a smaller secondary mirror 60 (claim 11ii). At the vertical center axis of the reflector basin is positioned a converter unit 30, all of which is encased in a protective container 40. There may be a separate support element for the container or a part of the container may form a support structure. Either case is denoted as 45.

Examples of plural mirror embodiments of the present invention are described in FIG. 8.

A preferred plural hollow mirror embodiment is made using twin sheet thermoforming. One sheet includes at least one reflective layer, such as an aluminized plastic film. The other sheet is transparent, such as an acrylic sheet or ETFE film. During forming, the reflective sheet is pressed against a forming tool that contains a plurality of tightly packed hollows shaped according to claim 8. The shape of the tool should facilitate the forming of a small hole in the center of each hollow in the sheet. The acrylic sheet may be of uniform thickness, or have thicker regions and thinner regions that correspond to the pattern of hollows, positioned such that the thicker regions act as lensoidal elements in the final plural concentrator. The two sheets are welded together at contact points where the forming tool protrudes maximally, which may be at points or ridges. To complete the functioning concentrator, converters are fitted into the holes at the bottom of each mirror.

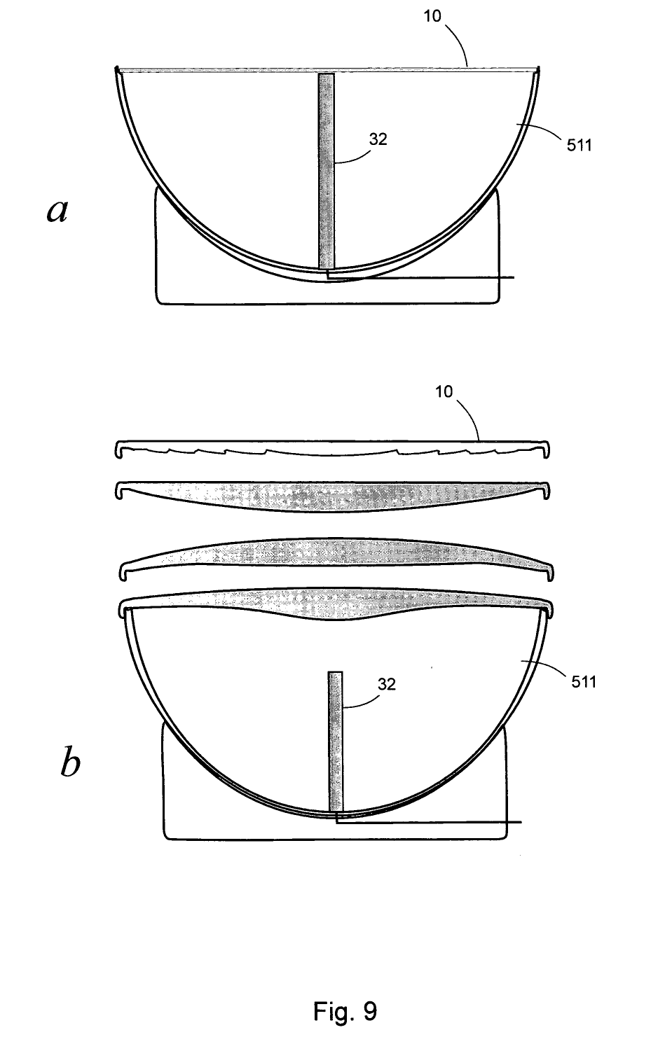

Another preferred plural hollow mirror embodiment uses twin sheet vacuum forming of films rather than sheets. Instead of a reflective sheet, a laminated film is used, including at least one reflective layer, such as an aluminized plastic film, and one electricity-conducting layer in the form of a flexible grid connecting regularly spaced PV converters. For example, the reflective plastic film may have regularly spaced small holes through which rod-shaped PV converters are inserted from the electric grid layer. The lamination tool has holes to accommodate the converters. The twin sheet structure is subsequently formed from this laminate and a transparent film of uniform or varied thickness, such as an acrylic or ETFE film, pressing the laminate against a forming tool that contains a plurality of hollows shaped according to claim 8 and sized such that each converter is positioned at the bottom of each hollow. The protusions of the tool form a lattice of ridges, which generate a continuously sealed contact with the transparent layer around each hollow. The resulting structure is an inflated bubble wrap that encloses a plural concentrator.

Where the concentrator consists of separate and self-contained concentrator units (claim 10), a preferred embodiment consists of at least two parts; a container where the inside forms the reflector basin shape, and a converter (FIG. 9a). In addition a surface layer may form a transparent lid or membrane. The lid may have a flat or curved upper surface, and may have constant thickness or a lensoidal increase in thickness on the underside (FIG. 9b). A lens allows the concentration factor to be increased because the required converter area is smaller (for example in the case of FIG. 9, the converter rod is shortened). It may be affixed to the container by mechanical pressure in the form of a screw fitting, combined with silicon or a rubber ring, or the pressure may come from regularly spaced screws or clamping devices along the edge. If it is affixed to the container with chemical bonding, this may for example take the form of a silicon wedge around the periphery.

The lid may be made by injection molding of acrylic resin or another transparent plastic, and the membrane may be a transparent ETFE film. The container may be made by vacuum forming of any suitable plastic, such as HDPE. It may for example be co-formed with an aluminized plastic film (e.g. Mylar), or by vacuum forming of a single aluminized thermo-plastic sheet. The container may also have a separate aluminized plastic film affixed to the inside, for example by chemical bonding. Said film will then first have been cut to fit the reflector form. Alternatively the mirror concentrator, whether in the form of a singular or plural mirror, can be made by twin sheet vacuum forming of a transparent sheet and a reflective sheet (for example an aluminized sheet), in which case the connection between them is permanently sealed by edge welding.

Separate and self-contained round units may for example be used as large, but lightweight concentrators suitable for small and medium-sized power plants, wherein each unit typically has more than one square meter incidence area, and wherein a plurality of such units are affixed to an external support structure, or each unit is affixed to neighboring units.

In another preferred embodiment of the round or trough-shaped concentrator unit, the separate and self-contained concentrator unit is an inflatable container made from two plastic films welded together at the edges, one transparent, and one with a reflective surface on the inside. Said arrangement when inflated forms a balloon, which is a separate container filled with air that has a transparent surface layer and a round reflector basin. When said container is fabricated in the simplest possible way, using two round films of the same size and shape, the reflector profile will be elliptical with the vertical axis orthogonal to the axis containing the geometric focal points. This geometry yields a highly inefficient concentrator.

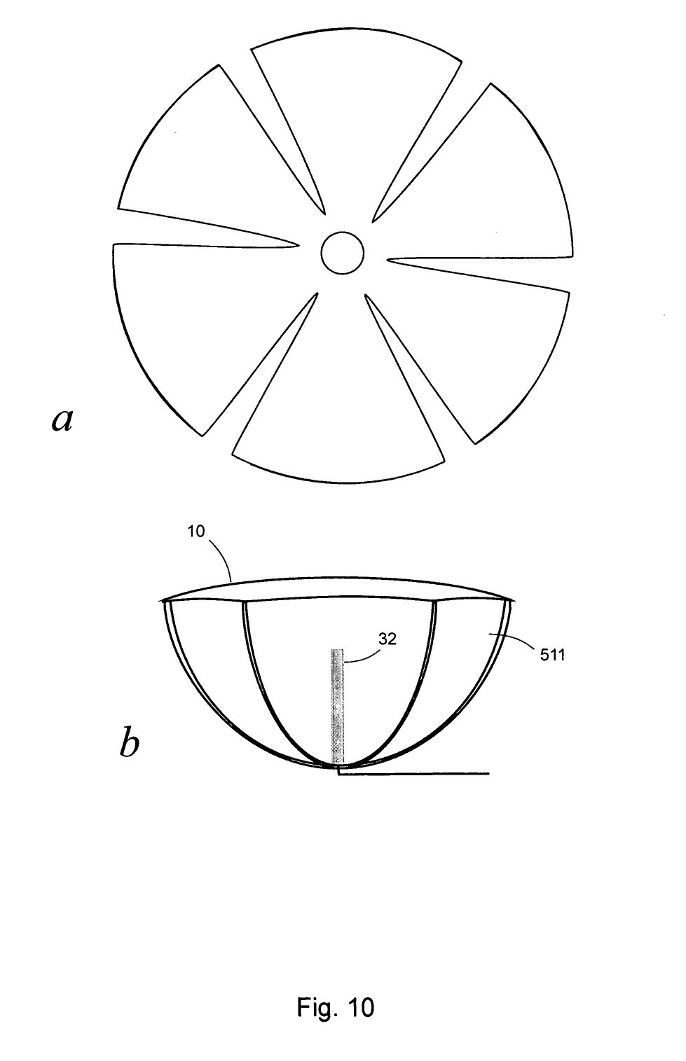

A preferred embodiment may therefore use a dome-shaped thermoforming tool in the form of an ellipsoidal, cycloidal, or catenary dome (hereafter referred to as a “dome”) to form the aluminized film, for example an ETFE film. Without ability to stretch, the metalized film will fold locally, and these folds are then thermoformed using an inverted plug, since plastic layers are everywhere in contact inside the folds. To ensure the flattened folds stay in place, an extra plastic film may be welded to the non-reflective side. If the aluminized film is not pliable enough to allow orderly folding, an alternative embodiment is manufactured in the following way. First, a plurality of deep, wedge-shaped incisions are cut into the round sheet that will form the reflector. (FIG. 10a). Next, the film is draped over the dome for example by pressure forming and welded at the incision edges so that the incisions are closed. To ensure sealed closure, an extra film may be welded to the non-reflective side (hereafter this entity is referred to as a “reflective bag”).

The dome tool is then removed, and the film is thermoformed with a transparent film using the twin sheet method to create a sealed and inflatable container with a reflector shape according to claim 8. In a final step, the converter and air valve may be inserted through a small central hole in the reflective layer, and the connection sealed, or they inserted earlier in the process, as described in the bubble wrap embodiment (FIG. 10b).

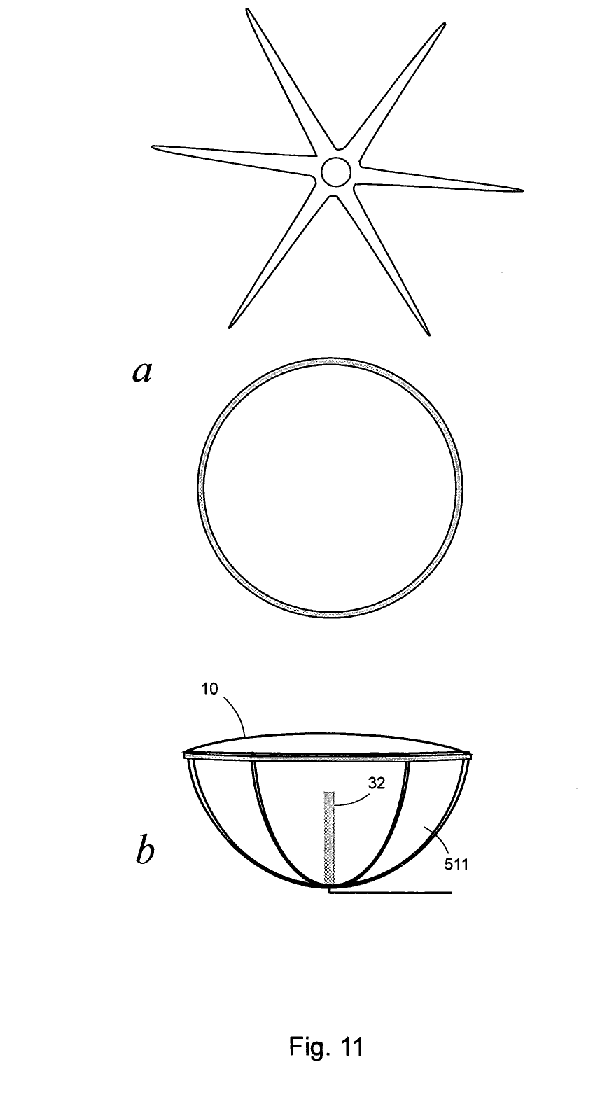

Another preferred embodiment is a round or trough-shaped concentrator in the form of a self-supporting tensile or tensegrity structure (FIG. 11). For example, a tensegrity structure may be formed using a planar or weakly curving flexible ribcage structure (hereafter referred to as a “ribcage”), for example made of plastic, consisting of a set of ribs attached for radially to a small central ring with a diameter that is not smaller than the central hole of the reflective sheet. The ribcage is held in tension in a curved position by at least one ring with the same diameter as the large opening of the container that is attached to the ribcage at, or close to the tips of the ribs. The ring forces the ribcage into an ellipsoidal, cycloidal, or catenary three-dimensional shape by exerting a compressive shear force on each rib. The ribcage is thus held in a state of global tension by the local compression force exerted by the ring where it is in contact with the ribs. This means the ribcage will exert a tensile stress on an attached reflective sheet, especially if the ring is made from a material that stretches moderately.

To manufacture a singular concentrator unit utilizing said tensegrity structures, a reflective bag is pulled over a dome tool, then a ribcage is pulled over the bag and welded to the back of it, such that the central ring is centered on a central opening of the bag. A plastic ring is then pulled over the outside of the ribcage. If there is only one such ring, its diameter is slightly larger than the large opening of the container, and it is affixed to the ribcage, for example by welding, in a position at the tips of the ribs or close to the tips. More than one plastic ring of different diameters may be used in order to ensure the resulting structure has and maintains the correct shape after the dome is removed. The dome is removed from the resulting container, which may stay open or be closed, for example by welding a transparent plastic film, such as an EFTE film, to the container rim. Finally the converter is placed within the container through the small opening. If the container remains open, the converter may be coated with a protective layer of ETFE.

In another embodiment of a tensegrity structure, the ribs may be tangential to the central ring instead of radial. The tensegrity structure can then be formed by folding two tangential ribcages over a dome and welding them together, such that the ribs form a rhombic pattern. In a further embodiment, a concentric ribcage if formed from a plurality of rings of different diameters, connected via radial or tangential spokes to form a tensegrity ring structure in three dimensions. The ring structure may be formed by welding the ribs to a second ribcage and push the structure into a dome shape using a dome plug. When either the concentric or rhombic ribcage is pulled over a separate inner ribcage and the two welded together at the central ring, a tensile open container skeleton is formed. The reflective bag may be affixed to the inside of it, or sandwiched between the ring structure and the ribcage. The resulting container may be closed by a transparent surface layer, such as an ETFE film, which may further be held in tension if the skeleton sets into a shape with a slightly larger diameter after completion of the container.

The one-mirror method (claim 11i) focuses the light onto a vertical line at the center, and thus requires a converter shape capable of utilizing this fact, e.g. a rod-shaped converter (32). The concentration factor is typically in the range of ×15-25 with a rod-shaped converter, and ×5-15 with a plural converter (33). The method gives substantial control over the range of angles with which most of the light reaches the converter.

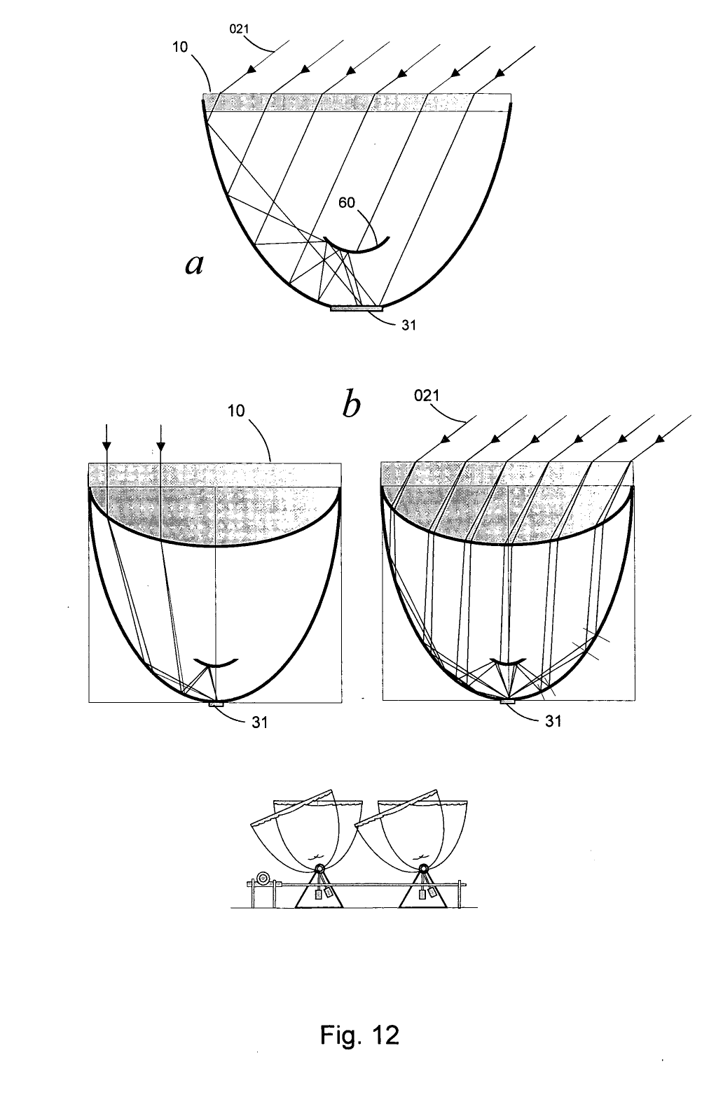

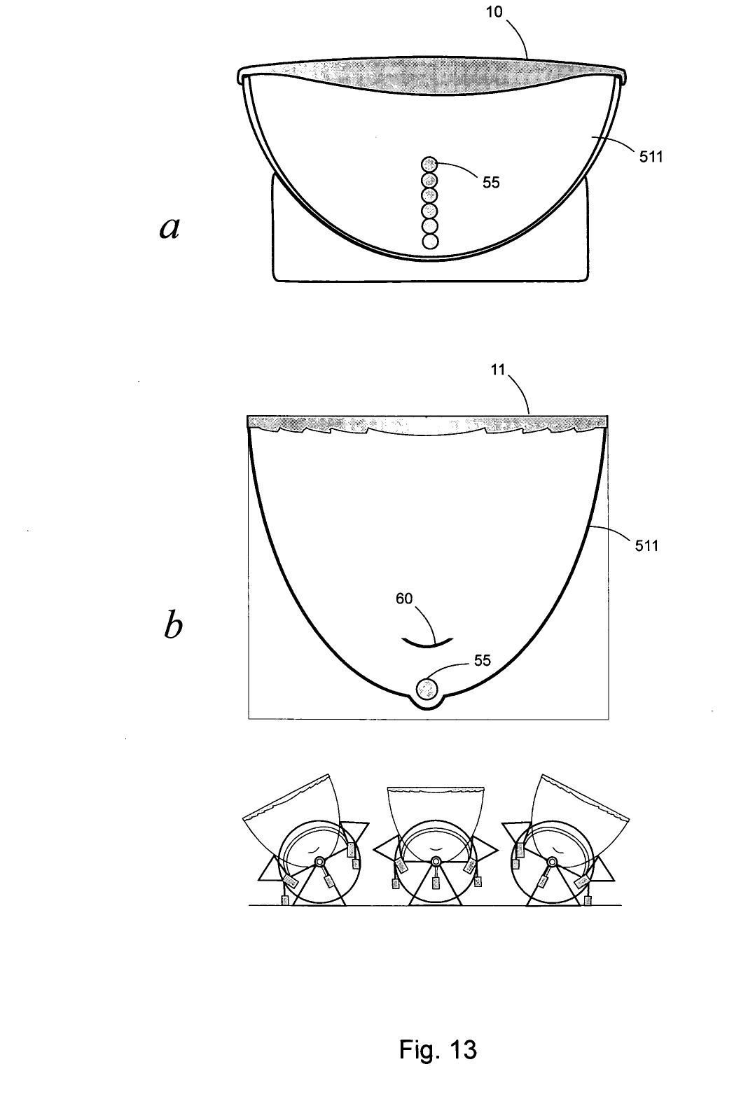

The two-mirror method (claim 11ii) allows the use of a small PV cell or continuous set of small PV cells (31) and therefore a high concentration factor (claim 12ii), typically in the range of ×20-200 but gives little control over the angle with which the light reaches the PV cell (FIG. 12). The two-mirror method is different from the Cassegrain telescope mirror concentrator. The latter uses a parabolic concave primary mirror and a hyperbolic convex secondary mirror (i.e. the Cassegrain telescope arrangement) for obtaining a very high concentration factor, but requires precise tracking. The two-mirror method as disclosed herein uses elliptic, cycloidal or catenary primary and secondary mirrors instead of parabolic and hyperbolic mirrors. This difference constitutes a method that allows the concentrator to be static. It is also a method that allows any tracking to be significantly less precise than required with the Cassegrain concentrator method (FIGS. 12b and 13b). FIG. 12b shows that the two-mirror method effectively reduces or eliminates chromatic aberration introduced by a surface lens, and therefore further is a method for this purpose.

In the case of the trough-shaped concentrator unit, the two-mirror method concentrates the light along the horizontal centerline of the trough, and hence requires the electricity converter to take the form of a strip of PV cells in said position. The use of trough-shaped concentrator units requires less reflector and container material than round concentrator units, and allows a better utilization of available land area when a tracking device does not have to be accommodated.

In the case of a trough-shaped concentrator unit, the one-mirror method concentrates light onto a vertical plane at the horizontal centerline of the trough. This embodiment allows the mirror concentrator to be used for generating thermal energy. The converter may then for example take the form of a plurality of parallel pipes (55), located in said vertical plane, that transport steam or another heat transport fluid to a heat storage unit or a turbine (FIG. 13a). The mirror may be made from polished and curved aluminium sheets, or vacuum formed plastic sheets with a highly reflective surface. Likewise in the case of a trough-shaped concentrator unit the two-mirror method can be used to heat a single heat transport pipe at the horizontal centerline of the trough (FIG. 13b).

Said separate and self-contained trough-shaped units may for example be used as large concentrators suitable for large solar thermal power plants, wherein each unit typically has more than a thousand square meter incidence area.

We now describe the transparent surface layer and container or casing common to both light tube and mirror embodiments of the concentrator panel. The basic purpose of the surface layer is to act as an isolating and protective cover for the light concentrator system. In one embodiment the surface layer has only this basic purpose (claim 14i). In this case it could be cut from a sheet of acrylic, glass, or other transparent material, or be a stretched polymer film or inflated bubble. It could also take the form of a surface coating of a transparent polymer. Said polymer film and surface coating could for example be made from the self-cleaning material ETFE.

When the surface layer has the Fresnel or planoconvex lens arrangement described by claim 14(ii) and 14(iii), the layer also functions to make the conditions of light entry into the concentrator more efficient under conditions of low incidence angle. In a preferred embodiment with this function there is a gap between the tube openings and the surface layer (FIG. 1). The gap is filled with an intermediate layer of low refraction index such as air. The surface layer may for example be manufactured by injection molding of acrylic resin. The layer may have a planar surface, or be gently curved to maintain its shape if the span is large. In another preferred embodiment the layer is in optical continuity with the concentrator (claim 14iv) and is either planar or has a plurality of lensoidal protusions at the surface. The concentrator and surface layer may then be manufactured in a single step, for example by injection molding of acrylic resin.

Where the concentrator collects thermal energy, it is known in the art that improved infrared light transparency may be achieved by doping of the surface layer and any filled concentrator embodiment with Germanium (Ge), and that improved conversion of infrared light to electricity may be achieved using Ga—As/Ge PV cells. Furthermore, it is known in the art that if a solar concentrator uses a material that over time degrades and becomes less transparent due to UV light, such as a plastic with moderate UV resistance, a polaroid or other UV-reflective coating of exposed concentrator surfaces may be used to reduce the problem. For the same purpose, the surface layer may be made from a material with low UV transparency, such as ETFE or glass in order to limit exposure of the concentrator.

The protective container or casing of the concentrator panel (claim 15) may for example be made from plastic, glass, ceramics, or a metal, using well-known methods such as vacuum forming. The surface layer may be affixed to the casing by mechanical pressure, for example using snap-on features or regularly spaced screws along the edge, and sealed with a silicon or a rubber ring. If the layer is affixed to the container with chemical bonding, this may for example take the form of a silicon wedge around the periphery. If an airtight sealing method is used, the enclosed space may be evacuated, and the resulting difference in air pressure contribute to the strength of the seal. Evacuation gives the panel an additional insulating quality. If the casing is made from a transparent material and a filled concentrator is used, the panel may further be used as a translucent glazing.

The casing may also function as an energy co-generator and means of active cooling of the converter. In the latter case it contains a separate chamber wherein a heat transport fluid can circulate, either within the chamber as a whole, or inside a pipe arrangement fitted into the chamber.

Finally, depending on their use, concentrator panels in accordance with the present invention can be used for conversion of sunlight to electricity at a multiplicity of scales. The concentrator may take the form of a thin sheet-like panel for a car roof, using for example the filled light tube or mirror embodiment, or a roof tile shape, or a relatively deep box, for example when a hollow tube embodiment is used for a solar power plant. The mirror embodiment may further take the form of a large structure with the dimension of a thick sheet consisting of separate and self-contained concentrator units. These may be placed close together either within an external or internal frame or without any enclosing or interlinking frame other than a common substrate, such that they form a planar or gently curving concentrator field.

### The PV Converter

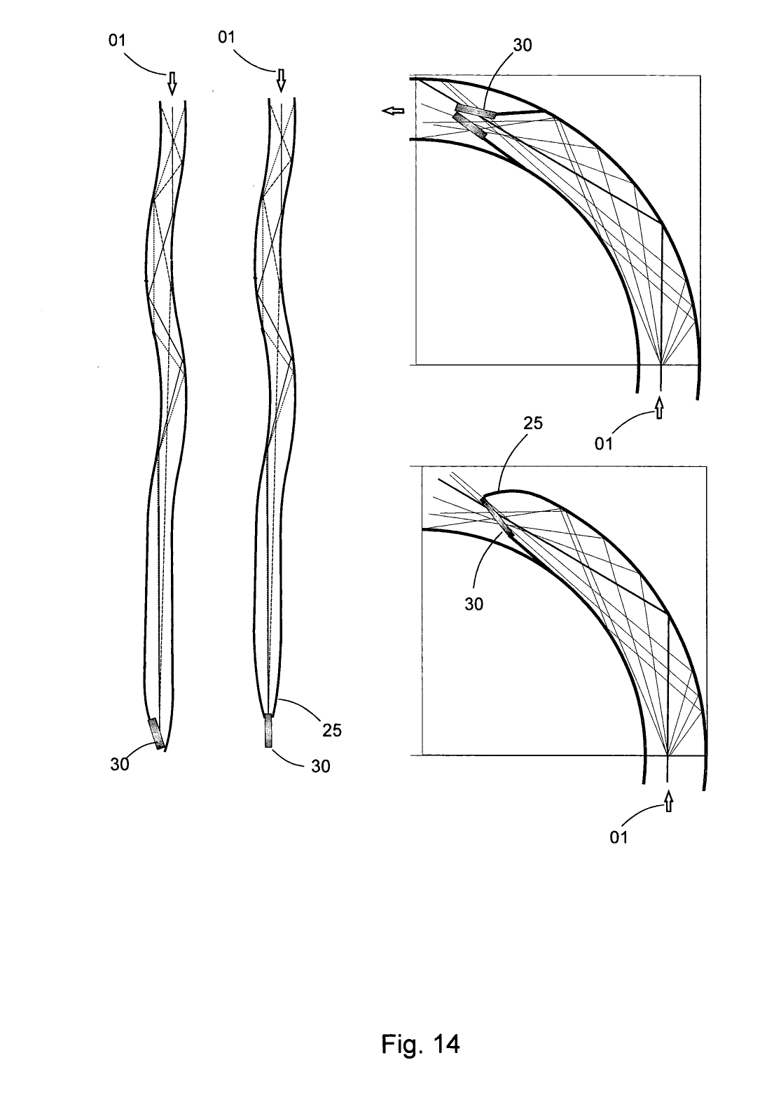

Claims 7 and 8 describe how a modular concentrator unit terminates in a singular converter, which may be a single photovoltaic cell that for example is square or round in outline. The PV cell may be positioned orthogonally to a straight or curved exit tube length axis. However, in a preferred embodiment the cell is placed at an angle to the tube length axis that differs substantially from 90 degrees, and is combined with a curved or curvilinear exit tube (FIG. 14). The curvature is chosen such that the bulk of the ray trajectories fall on the cell surface at a desired angle. To ensure as far as possible an even light distribution over the area of the cell, the final exit tube section before the cell (the diffuser) is modified by local curvature and tapering to a shape that reflects all light onto the cell.

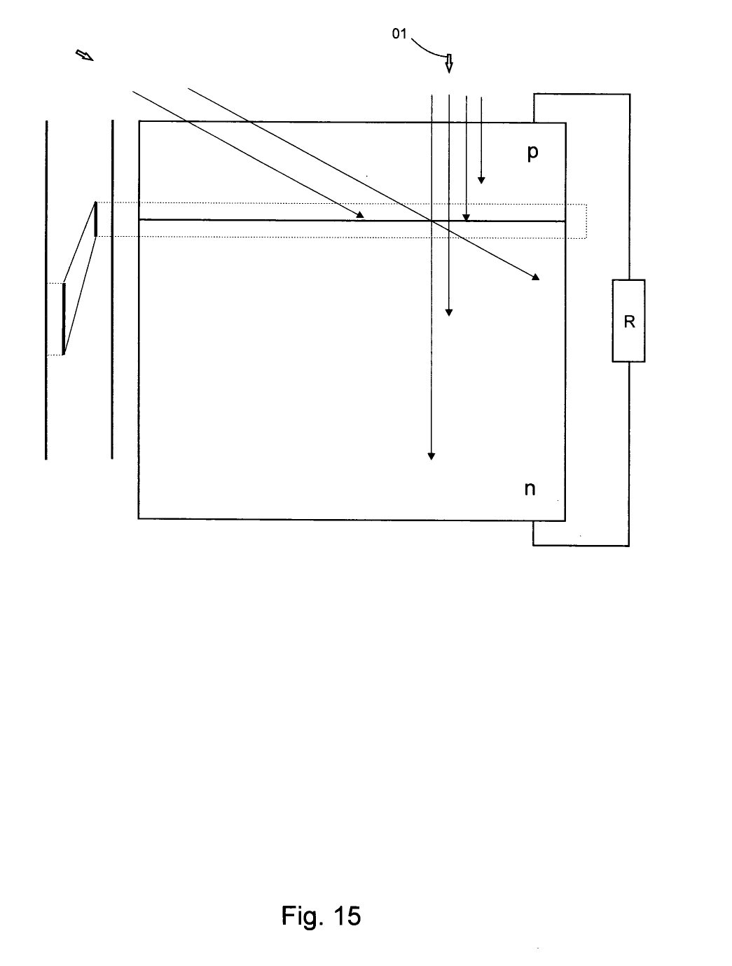

Said arrangements functions as a method of increasing PV conversion efficiency relative to a cell placed orthogonally to the exit tube centerline. Typical absorption coefficients of inorganic semiconductors imply light penetration depths of order 100 nm. However, only photon trajectories that terminate in a narrow band of 10 nm around the n-p interface contribute to the electric current (FIG. 15). Hence light that enters with an orthogonal incidence angle minimizes the fraction of light that terminates in the current-generating zone. Using the fact that the concentrator allows substantial control over the light direction and its variation, it is possible to ensure that most light falls onto the converter surface with a low angle. For example, at an angle of 60 degrees the fraction of light that terminates in the current-generating zone has doubled (FIG. 15).

An incidence angle exists for which the combination of increased zone thickness and depth position is optimal, and the present invention allows configuration such that most light reaches the PV converter at this angle. Hence a spatial converter shape and arrangement relative to a concentrator is disclosed herein as a method of optimizing PV energy conversion for any concentrator that uses light tubes or mirrors.

The converter may be either singular or plural (claim 7iii). A singular converter consists of a single PV cell or a plurality of PV cells arranged to form a continuous surface. A plural converter consists of a plurality of PV cells, for example in the form of PV thin films, that are not in continuity, but connected in parallel or series such that they connect to a single electricity outlet. A plural converter has a spatial arrangement of said cells that functions as a method of reducing or minimizing the mean light incidence angle.

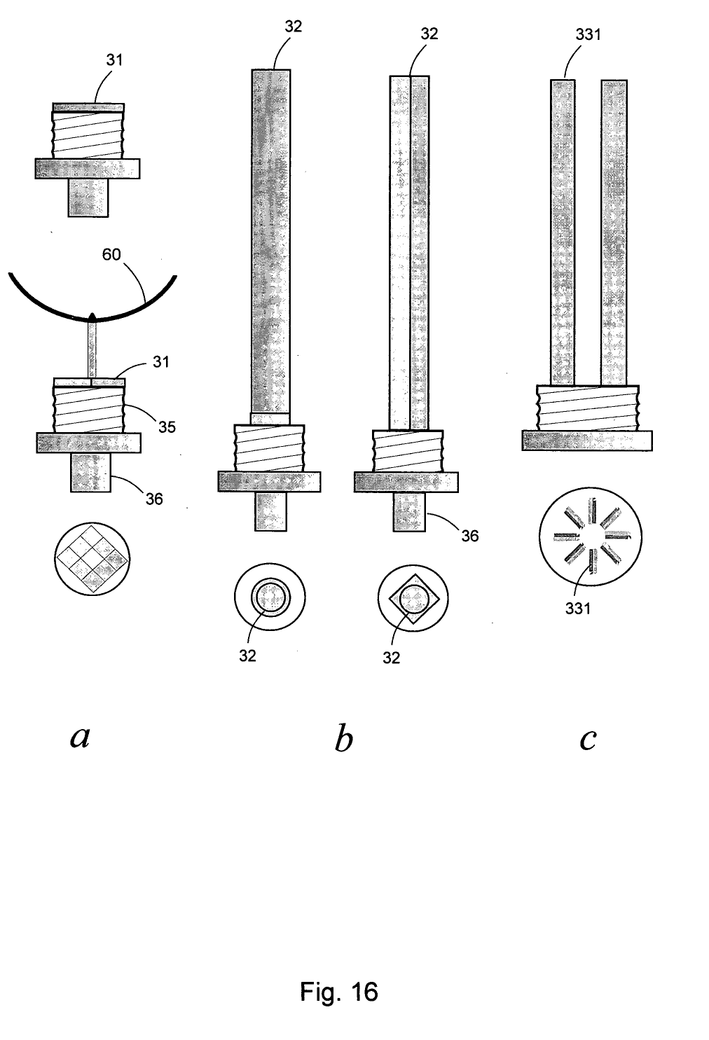

A converter as described herein consists of one or a plurality of PV cells mounted on one or a plurality of rigid substrates that supports and holds each PV cell in their prescribed position relative to each other and the concentrator (FIG. 16). Said substrates are mounted on a platform (35) in a manner that allows an electric current to be transported from each converter element into the platform (claim 7iii). The platform further has an electrically insulated means of affixing to the concentrator, such as threading for a screw fitting. A heat pipe (36) may pass through the platform. In the case of a plural converter, the platform internally connects each converter element in parallel or series and transport the total current to an external connection point, usually on the underside of the platform, which connects the converter to an external electric circuit. Said external circuit may in turn be the internal circuit of a modular concentrator panel or field, connecting each converter, for example in series, to a common outlet for the whole concentrator panel or concentrator field.

Claims 8 and 13 describe a singular converter in the shape of a rod (FIG. 16b). In one embodiment the rod is a cylinder such as a heat pipe around which is wrapped a flexible photovoltaic material, such as a CIGS thin film. Alternatively, a photovoltaic thin film is deposited on the surface. In another embodiment, small square or rectangular photovoltaic cells are mounted on the sides of a square peg, used instead of a cylinder. Hence this converter type does not depend on the use of a photovoltaic thin film. In further preferred embodiments the rod either has high thermal conductivity or is a heat pipe that connects to an external heat sink.

Claims 8 and 14 describe a plural converter in the form of a radial and concentric arrangement of converter elements (331) (FIG. 16c). With this arrangement most light falls onto one or several photovoltaic surfaces at a low angle, thus increasing the conversion ratio. Relative to a singular converter, a plural converter also functions to reduce light loss caused by reflection from the concentrator.

### The Heat Storage Unit

The heat storage system of claim 17 consists of a hot core embedded in an insulator, and the application of two methods for reducing heat loss from the core (claim 17ii and 17iv). The system thus maintains the core temperature above a critical threshold for a specific time interval under continuous extraction of energy in the absence of external heat supply.

The methods follows from Fourier's law of heat conductance. The heat equation describes the heat profile between a hot and a cold region according to Fourier's law and the law of conservation of energy. The control parameter is the ratio of thermal conductivity to the product of specific heat capacity and density. The lower this ratio, the lower the temperature gradient.

Method 1: A qualitative three-component structure is provided, composed of a hot core, an outer insulating zone, and a transitional zone between them, such that the transition zone is insulating relative to the hot core by having lower thermal conductance, and heat storing relative to the outer insulating zone by having a larger product of heat capacity and density. This zone thereby functions both as a secondary heat storage element and an insulating layer. The heat storing capacity of the transition zone is further increased by using a material that undergoes a phase change above the critical temperature.

The purpose of this arrangement is to reduce heat loss over a range of core temperatures and thus maintain a sufficiently high core temperature for as long as possible. Since heat is extracted from the core as thermal work, the temperature of the core decreases not just by heating up the surroundings, but also due to work. Gradually the temperature becomes higher in the transition zone than in the core itself, and heat begins to flow from the transition zone back into the core. If a phase-change material is used in the transition zone, the secondary heat inflow is prolonged.

The inner hot core contains a material with both high thermal conductance and a large product of high heat capacity and density (e.g. concrete) that may also be a phase change heat material (e.g. saltpeter salt).

Preferred embodiments of the invention do not relate to specific materials, only their specific heat flow and heat capacity properties, so that many different materials may be used in any given zone or layer to achieve the physical properties prescribed by the method for said zone or layer.

Method 2: Provide a quantitative zoned arrangement of the material surrounding the hot core, wherein the zonation is guided by the temperature profile of a uniform material extending from the hot core to the outside surface of the heat storage unit.

Method 2 consists of five rules:

1. Minimize the sum of the product of the thickness of the two zones and their heat equation proportionality factor.

2. Where there are more than two zones, they must be arranged according to a decreasing product of [thermal conductivity×heat capacity×density] from the inside to the outside of the whole structure.

3. Where there are more than two zones, they must also be arranged according to a decreasing thermal conductivity, and decreasing density from the inside to the outside of the whole structure.

4. The fully developed temperature profile has two regions, an inner plateau and an outer zone of rapid temperature drop. For the outer zone, materials should be chosen with very low conductivity and proportionality factor, and for the inner zone materials should be chosen based on a large product of heat capacity and density.

5. Choose relative thicknesses of zones by a two-step procedure:

First, find thicknesses such that their difference is weighted according to the difference in area under the equivalent sections of the fully developed temperature profile of a uniform material, starting from the boundary of the hot core, given the specified initial temperature difference from the core boundary to outside (when heat supply to the core ceases).
Second, shift the starting point to the edge of the plateau region (at the point where an inner zone has been differentiated), and use the same approach again. This corresponds to the development of the heat profile during the storage period, which eventually peaks in the transition zone as heat is extracted from the core and converted to work. Hence the new start point has a lower temperature than the initial one. The new profile plus the shift distance yields the minimum thickness of the whole zone. Further differentiation into subzones now becomes possible, based on differentiating again between the plateau zone and the temperature drop zone, taking into account that for each new zone rule 1-3 applies. The process can be repeated further, but with diminishing returns for each new zone. If the process is repeated, a stepwise gradation between the initial transition zone and insulation zone results.

In a preferred embodiment, the zones are graded into different subzones with different thermal conductance and heat capacity properties in order to match heat flow and distribution profiles more closely. Where there are steps in properties between layers, and thus accelerated heat flux relative to the flux within the layers, these layer boundaries may have one, or a plurality of membranes or coatings of a heat-reflective material, such as aluminium (e.g. Heat Shield) that reduces radiation heat loss. Also sealed vacuum layers may be used that reduce convective heat loss. Barriers of this kind are most usefully positioned between the transition zone and the insulating zone.

In further preferred embodiments, the transport tubes may terminate within the transition zone or inside the core, but since these tubes become conduits of heat loss at night, in a preferred embodiment the transition zone has three or more layers, where the tubes go through the outer layer, and continue within the middle layer as a heat-absorbing black body cavity, while the inner layer facing the core is everywhere continuous. In another preferred embodiment the tubes pass all the way through the transition zone, and terminate in black-body cavity continuations extending some way into the core.

In other preferred embodiments the heat diffuser tubes may enter the heat storage unit radially or tangentially, so that the heat flow is directed towards the center and has a large contact area within the core and transition zone. Furthermore, the tubes can be closed in the outer zone with blocks of a lightweight insulating material, using a motor arrangement that slide said blocks sideways into the tubes, thus strongly reducing heat loss. A further method of reducing heat loss is to make the heat diffusers taper strongly as they enter the storage unit.

The heat storage unit can be built from relatively inexpensive materials as long as they are stable under operating temperatures. Each zone may be compartmentalized with breeze blocks or a ceramic material. An inner core may be a phase change material that can store latent heat, for instance as molten salt. An outer core may be made from cast iron, or a composite material, for example a mixture of concrete and graphite or corundum, or rubber embedded in asphalt, both combining medium conductivity and heat storage properties, or the whole core may contain a single phase change material. Likewise basalt, gypsum or wax may for example be used for the transition zone, and polystyrene, tufa or pumice may form the insulating zone.

The heat is used to produce steam to drive a turbine via a pressure boiler that in one preferred embodiment is a separate pressure chamber located directly above the roof of the heat storage unit, and covering the area of the core or both the core and some or all of the transition zone. The interface between the heat storage unit and the boiler may be an insulating zone, for example to transition zone level, and contain heat exchange elements in the form of wells or pipes with thermally conductive walls that descend into the core from the boiler. This simple arrangement reduces cost and heat loss. In a preferred embodiment, the boiler is further heated during daytime directly via exit tubes while the heat storage unit is rebuilding temperature. The boiler connects to a turbine, which further connects to a condenser tank.

The Concentrator Support Structure

Unlike current solar thermal plants and PV plants the system disclosed herein allows dual use of the land area physically occupied by the concentrator. There are two reasons for this: First, it is static and thus does not require a fixed, heavy ground support as inertial counterbalance, and second, the modes of concentration provided allows the concentrator to be made from lightweight materials, such as plastic. The methods that provide these properties of the system are further claimed herein as methods of providing the system with a dual land-use capability (claim 19).

A large variety of light weight support structures with limited load-bearing capability are known in the art, employing for example linear elements such as beams, arches, pylons and tensegrity structures. The use of such structures for supporting and suspending a static solar concentrator field above ground is claimed as a part of the invention. Preferred embodiments include the use of a scaffolding of bamboo or impregnated paper rolls. Another preferred embodiment is an open tensile weave of ropes or cables, such as nylon, polyester or manila ropes. For example, interlaced parallel ropes in three directions provide a tensile network of equal-sized triangles, each of which may support one or three concentrator units. The latter may be either interlocked or enclosed within a light external frame, for example made of bamboo. Similarly a rhombic network pattern may support sets of four concentrator units. Alternatively a thin mesh-like weave may be used. In either case, the suspended net is supported at regular intervals by poles or arches affixed to the ground, forming for example a cellular framework. Another preferred support structure embodiment is a thin-shell tensegrity structure, for example in the form of a lattice shell structure, wherein may be inserted for example curved or planar concentrator panels according to the invention.

The concentrator acts to shade the surface below, but many degrees of shading are possible with the system. For example, the concentrator field may have openings between concentrator units, or the concentrator units may be translucent (if panels based on filled embodiments), or the concentrator field may form a closed and watertight roof if the incidence area is complete utilized for sun capture. Hence a number of dual uses are possible. A suspended concentrator field will shield plants from extreme desiccating sunlight, and in general cool the surface and reduce evaporation. Hence the system can be used for the dual purpose of either reforestation or cultivation of specific plants that thrive in semi-shade or deep shade. Furthermore, the area underneath the concentrator can further be fully or partially enclosed, using for example EFTE film, and thus function as a green house, for example in conjunction with hydroponic cultivation. A closed roof embodiment allows the area underneath to be turned into an enclosed space, suitable for example as a storage depot or industrial facility.

The invention includes a simple tracking device. In a preferred embodiment a trough-concentrator field is linked via a drive shaft to a computer-controlled motor that moves the shaft backwards and forwards (FIG. 12b). In another preferred embodiment round mirror concentrators are counter-weighted and mounted on a suspended beam or rope at the center of gravity point, while the weights are connected via ropes to pulleys and motors at opposite sides of said concentrator field. In another preferred embodiment, the tracking device is solar-driven, using an oscillating apparatus based on adjustable weights (FIG. 13b). The concentrator is affixed to a wheel which has two fixed weights and adjustable weights at the perimeter. The adjustable weights are two containers half-full with a fluid connected above fluid level via a heat-insulated tube. Each has a glass surface and attached Fresnel lens, so that sunlight can evaporate the fluid in one tube, which then is condensed in the connecting tube and cumulating in the opposite container. As the sun moves, the wheel rotates. Instead of a wheel a grid forming a ball can be used in order to provide 2-dimensional movement.

Adaptations that Allow the Concentrator to Float on Water

Unlike current PV plants, the system disclosed herein allows the concentrator field to float on water. The surface of a lake or bay, while relatively sheltered, is a dynamic and corrosive environment that will subject the concentrator field to mechanical stresses, and potentially also water damage and rapid clouding of the surface layer due to salt spray and colonization by birds. In order to overcome these problems the invention comprises a set of adaptive methods that allow the system to function efficiently with low maintenance when located on a lake or in the sea. The system further provides dual use as a trawl-free shelter for fish and includes a method of sustainable fishing.

One preferred embodiment of the floating system takes the form of a floating concentrator field of mono-hull buoyant mirror-based containers able to self-correct their vertical positioning if overturned. Each is given a low centre of gravity sufficient for self-stabilization by affixing to the underside of the container a ballast element, compartment, or object. Each unit is mechanically connected to its nearest neighbors. The connections may be positioned at triple points. They may be rigid, flexible, or jointed, and include a fender.

In another preferred embodiment, the concentrator field consists of a plurality of panels or containers, covering a plurality of fendered buoyant pontoon rafts made for example from foam-filled plastic cylinders or empty or foam-filled steel barrels or that are rigidly connected to each other and support a platform in the manner of a catamaran. The structure may be rectangular like a pontoon boat, or form an angular structure, e.g. a hexagonal or triangular. In the latter case the buoyant pontoon structure may be a single rigid closed unit, or consist of six separate units. The center of the platform may be supported by arched or linear struts or beams that connect a central element to the buoyant structure. The central element may take the form of a ring or angular closed shape (e.g. a hexagonal). It may also be a vertical pole relating to the pontoons in the manner of a tripod.

Said embodiments are suitable for low to medium wave-energy environments, such as lakes or sheltered bays. Another preferred embodiment adapts the catamaran pontoon structure to function in an open marine environment by using a SWATH design for reducing wave impact energy (by positioning the outrigger hulls below the waterline). Furthermore, if a plurality of pontoons is used, each pontoon may be given capacity for absorbing some local wave motion by using joints that allow restricted rotational movement at the central element instead of rigid connections. The structure may be further strengthened by adding spokes, struts, or beams which connect opposite pontoons below the waterline, or connect the pontoons to second central element below the waterline. The two elements may be further connected to a central vertical pole, which may further be attached to a central ballast element.

The buoyant structure is fendered, for example by attaching beams to the pontoons that run parallel to the pontoons. These beams are threaded with small reused vehicle tyres. The beams are further co-threaded with the beams of neighboring units using larger tyres that alternate with the smaller ones. Said use of tyres allow for a fendered mechanism of interlocking neighboring units that flexibly absorbs both compressive and tensile stresses. The cross-bars connecting the beams to the pontoons may have joint connections in order to allow further relative movement. Another embodiment that further allows the structure to absorb rotational movement uses semicircular beams instead of linear ones.

In a preferred embodiment, the surface layer of each floating unit is an ETFE film, stretched over a frame that gives a spire-shape too steep for birds to land. On lakes where birds and salt spray does not present problems, the surface layer may be a curved acrylic lid or a curved ETFE cushion.

Preferred embodiments of the global barrier (claim 20iv) are a static wave breaker extending from the sea bed, and a floating wave breaker in the form of a single or double array of rafts with a low center of gravity, attached to each other and anchored to the sea bed or to land. In the latter case, each raft consists of a material such as plastic or concrete with a prefractal hollow structure or surface indentations, such that wave energy is efficiently dissipated rather than merely reflected. In another preferred embodiment the wavebreaker consist of a chain of wave energy converters anchored to the sea bed.

A preferred embodiment of the fish trapping device (claim 20v) takes the form of a wide enclosure that is open at each end and extends into the water, and wherein the underwater end is blocked by an attached fishing net with openings that correspond to sustainable fish size. The enclosure has wall openings that allow entry of fish larger than the sustainable size, but exit only of fish that are smaller. This one-way effect is caused by the presence of semi-rigid, but flexible spikes lining each opening and oriented at a high angle into the enclosure. Said units are located around the periphery of the concentrator field where they can be accessed by boat.

What is claimed is:

1. A system for utilizing solar energy, or any component thereof, comprising:
(i) a method of light concentration embodied in the form of a light concentrating apparatus (hereafter referred to as “concentrator”), where “light” refers to solar radiation in both the visible and infrared part of the spectrum, based on an arrangement of either light tubes or mirrors that guide the light to an energy conversion element (hereafter referred to as “converter”), and
(ii) a method for optimizing the energy conversion ratio wherein the concentrator exit structure and the converter are co-adapted for the purpose of light control, and
(iii) a heat storage method that reduces and controls the rate of heat loss, and
(iv) structural support methods for locating the concentrator above ground or on water, and wherein said concentrator has a flat or gently curved surface, and capacity for collecting light through a range of incidence angles from orthogonal down to at least 45 degrees deviation from orthogonal, and capacity for operating within, but not limited to, a range of ×5-1300 concentration factor.

2. The system of claim 1, using as the method of concentration a plurality of light tubes, wherein either:
(i) said light tubes are of different cross-sectional area, such that the ends of the tubes with the smallest diameter (hereafter referred to as “entry tubes”) open up to the concentrator surface and act as an entry zone for light, and wherein said entry tubes guides the light into one or a plurality of tubes of larger size, such that the light is concentrated into a single light exit tube that has the largest diameter of the complete set of tubes and leads directly to a converter (hereafter intermediate light tubes between entry and exit tubes are referred to as “transport tubes”), or
(ii) said entry tubes are also exit tubes.

3. The method of claim 2, wherein an arrangement of light tubes that terminates in a single converter (hereafter referred to as a “singular concentrator”) is further extended to a modular light tube arrangement (hereafter referred to as a “modular concentrator”), wherein each singular concentrator forms an element, or module within said modular concentrator.

4. The method of claim 3, further comprising the use of a curved or curvilinear light tube shape, wherein the curvature radius is larger than 3.7 times the diameter of said light tube at the entry of any tube bend, as measured from the centerline of the light tube.

5. The method of claim 4, further comprising an exit tube and intermediate tubes of expanding cross sectional area, such that smaller tubes connect to said exit tube or intermediate tube via a connective tube section wherein the smaller and larger tube is either parallel or sub-parallel with up to 25 degrees angle, and wherein said connective tube section is a part of the larger tube and thus expanding the cross section area of the larger tube, and wherein the exit tube or intermediate tube has one of the following shapes:
(i) a curved tube of constant, increasing, or diminishing curvature gradient in two or three dimensions, or
(ii) a curvilinear tube in two or three dimensions, or
(iii) a circular exit tube or intermediate tube of expanding or constant cross sectional area (hereafter referred to as a “light control tube”) which forms a partially or fully coiled planar or minimally helical tube, and which functions to concentrate the angles of light ray incidence with the tube wall into narrowly range-bound domains (hereafter referred to as “light spots”).

6. The method of claim 4, further comprising the following set of methods for reducing light loss through the concentrator:
(i) a spatial light tube arrangement that locates transport and exit tube sections on the underside of the concentrator, and
(ii) an entry light tube arrangement that reduces entry loss, either by fusing the tube openings of filled tubes into a continuous surface layer, or by tapering the wall thickness of hollow tubes towards the light exit opening, and
(iii) further providing the internal tube walls of hollow tubes with photovoltaic (hereafter also referred to as “PV”) properties, and
(iv) reduction of light loss due to refraction of light above the critical angle for total internal reflection, by coating or covering the inside of the panel casing with a reflective material.

7. The method of claim 1, further comprising a converter with a cooling method in the form of either passive cooling, solid heat sink, heat pipe or the use of a circulating liquid coolant, and a connection from the exit tube to said converter, according to one of the following methods:
(i) an exit tube leads to a converter in the form of a tapering or branching hollow tube made from a heat-resistant material with high heat conductivity and a low-reflective surface (hereafter referred to as a “heat diffuser”), or
(ii) an exit tube leads to a converter in the form of a singular or branching distributive tube system that redistributes the sunlight to a space for illumination of said space via one or a plurality of diffuser interfaces, or
(iii) an exit tube leads to a converter in the form of a photovoltaic surface, which is either continuous, and consisting of one, or a plurality of photovoltaic cells (hereafter referred to as a “singular converter”) or discontinuous, and formed from a plurality of photovoltaic cells (hereafter referred to as a “plural converter”), and wherein the converter further includes a component that serves to electrically connecting the converter to a circuit and to affixing, either mechanically or by chemical bonding the converter to the concentrator (hereafter referred to as a “platform”), and a heat transport component such as a heat pipe or plate which may further connect the converter to an external heat sink.

8. The method of claim 7(iii), further comprising an exit tube, or the final section thereof, which functions as a light diffuser (hereafter referred to as a “diffuser”), such that the diffuser is a tapering curved or curvilinear tube section wherein light enters the largest opening of the diffuser and the converter is mounted such that it covers the smallest opening of the diffuser, and wherein either:
(i) a plurality of tapered light tubes connect to a singular converter such that all the tapered ends of the light tubes fit into or form the largest opening of the diffuser and the converter is mounted such that it covers the smallest opening of the diffuser, or
(ii) a curved exit tube and diffuser faces a singular or plural converter, positioned at a non-orthogonal angle to the exit tube midline, and wherein the diffuser terminates with a shape that matches and encloses the shape of the converter, or
(iii) the diffuser has an elliptic, cycloidal, or catenary tapering profile, and the converter takes either one, or a combination of the following forms:
a rod-shaped singular converter wherein a thin film or a plurality of photovoltaic cells cover a rod that extends into the tube along the tube centerline,
a planar singular converter located in an orthogonal and centered position relative to the exit tube centerline and positioned at the apex of the exit tube, and
a plural converter aligned with the exit tube centerline and arranged radially and concentrically around the centerline.

9. The system of claim 1, using as the method of concentration a concave mirror with either an elliptical, cycloidal, or catenary profile when seen in a vertical cross-section through the centerline, and where the geometrical focal point of said profile is located on the centerline, and wherein said mirrors are shaped as either bowl-shaped round hollows or protusions (hereafter referred to as a “round concentrator unit”, or concentrator units in the form of trough-shaped hollows or protusions.

10. The method of claim 9, wherein the concentrator units are either:
(i) hollows within a continuous reflective sheet or film, or
(ii) protusions from a continuous sheet of a transparent material wherein the protusions on one side act as reflectors according to the method of total internal reflection and the opposite side of the sheet is either planar or has a set of lensoidal protusions, or
(iii) separate concentrator units that are self-contained and which may be physically connected to one or a plurality of other such unit either by a direct interlocking mechanism or via an external support structure.

11. The methods of claim 10(i) and 10(iii), wherein
a continuous reflective sheet or film according to claim 10(i) includes the converters and the electrical grid connecting them, and wherein a continuous reflective film is bonded to a transparent surface layer at least at the edges of the film, such that the concentrator is sealed and inflatable, and
wherein a mirror concentrator unit according to claim 10(iii) takes the form of a hollow container which is either open or has a surface layer that either takes the form of a rigid, transparent lid, or a stretched plastic film, either of which can be closed such that the container is watertight, and wherein:
(i) the surface layer has an outer surface that is either planer or curved, and is made of a transparent material of either uniform thickness or including a lens, and
(ii) the container is either a rigid jar-like container, a tensegrity-based container, or an inflatable container, and
(iii) the container houses a singular reflector, which may form the inner surface of the container or be a separate layer or film that covers the inside of the container, and
(iv) said lid closes the container in a manner that seals the connection between them by mechanical pressure or chemical bonding, such that the connection is at least watertight, or both watertight and airtight.

12. The method of claim 9, further comprising a choice of two possible mirror arrangements within each circular concentrator element; either
(i) a single elliptical, cycloidal, or catenary mirror forming a light attractor basin by reflection (hereafter referred to as the “one-mirror method”), or
(ii) an elliptical, cycloidal, or catenary primary mirror forming a light attractor basin by reflection, combined with a centered secondary smaller convex mirror located near the geometric focal point of either the actual shape or the equivalent ellipse of the larger mirror, such that the geometric focal points of the two mirrors overlap, and wherein said secondary mirror is either elliptical, cycloidal, or catenary in profile (hereafter said arrangement of a primary and a secondary mirror is referred to as the “two-mirror method”).

13. The method of claim 12, wherein the energy converter is a singular converter consisting either of one photovoltaic cell for each circular concentrator unit, located on the vertical axis of rotation (hereafter referred to as the “center axis”) of each mirror and orthogonally positioned relative to said axis, or a plurality of singular converters positioned at constant intervals along the center line of trough-shaped concentrator units, such that the one-mirror and two-mirror methods have different singular converter arrangements:
(i) for the one-mirror concentrator, the photovoltaic element consists of a photovoltaic material that is deposited on, affixed to, or folded around a rod, such as a heat pipe, aligned with, and positioned on the vertical center axis of the reflection basin, whereas
(ii) for the two-mirror concentrator the photovoltaic cell is a flat disk centered on and located at the intersection point of the primary mirror and the center axis (hereafter referred to as the “center point”), such that the photovoltaic surface is orthogonal to the vertical center axis.

14. The method of claim 12, wherein the converter within each one-mirror circular concentrator unit, or each converter within the plurality of converters within a one-mirror trough concentrator unit, is a plural converter that either consists of, or includes the following arrangement:
a plurality of photovoltaic elements that are aligned with, and arranged concentrically around, and positioned radially relative to, but not reaching or crossing the vertical center axis, such that the center axis is the axis of rotation for the whole arrangement, and wherein each photovoltaic element either consists of photovoltaic cells affixed back to back or onto opposite sides of a support element, or consists of one or two thin-film photovoltaic cells deposited or affixed directly onto said support element, which may further functions as a heat sink.

15. The concentration method of claim 1, further comprising a transparent surface layer covering the light concentrator, and where one or both sides of the surface layer either have no optical or other coatings, or have one or a plurality of surface coatings such as may serve to reduce refraction, reduce transmission of UV light, or produce a self-cleaning hydrophobic surface, and where the surface layer is either:
(i) a single uniformly flat or gently curved sheet, or
(ii) a single, or a plurality of flat or gently curved sheets that have a multiplicity of Fresnel lenses embedded or engraved, each with a diameter and arrangement that either matches or is larger than the openings of light tubes or individual mirrors, and such that said lenses are located above said concentrator units without lateral offset, or
(iii) a single, or a plurality of sheets that are flat or gently curved and smooth on the side of light incidence, and on the underside has a multiplicity of convex one-sided lenses with a diameter that either matches or is larger than the opening of light tubes or individual primary mirrors, and wherein each single lens is located above each concentrator unit without lateral offset, or
(iv) a layer that is not separate from the concentrator, but the top surface of the concentrator itself, such that the surface is either flat or gently curved and smooth on the side of light incidence or locally lensoidal above each entry tube or primary mirror.

16. The concentration method of claim 1, in which the concentrator unit is encased in a rigid outer watertight shell, casing or container such that said surface layer forms a lid to said container in such a manner that said lid can be closed with a watertight sealing, wherein said container may further enclose a separate chamber below the concentrator wherein a heat transport fluid circulates, and wherein said container may consist of a frame and a back panel or laminum which may act as substrate and external heat sink for the converter.

17. The system of claim 1, wherein heat is converted to specific forms of work, including, but not limited to:
(i) a boiler or steam generator for driving a turbine,
(ii) a furnace,
(iii) a heat difference machine for cooling air, such as an air conditioner or a device using an evaporative cooling method,
(iv) an apparatus for desalination of saltwater,
(v) an apparatus for the liquefaction of a gas,
(vi) an apparatus for the production or concentration of a molecule that stores chemical energy.

18. The heat storage method of claim 1, comprising at least three of the following methods of using solar energy to heat a pressure boiler (e.g. steam generator) or furnace, such that said boiler or furnace maintains a temperature above a critical threshold overnight and under cloudy conditions:
(i) an arrangement of hollow light tube concentrators that transport solar radiation directly to said boiler or furnace via the curved exit tubes, heat diffuser and light transport method of claims 5 and 7(i), and
(ii) the use of one or a plurality of heat storage units (hereafter termed HSU) that take the form of a hot core surrounded on all sides or all sides except one, by at least two zones of insulating material such that the outer zone is highly insulating, and the inner zone is a transition zone that combines heat storage and insulating abilities that are intermediate between the properties of the core and the insulating zone, and wherein the core and transition zone are containers filled with, or consisting of a materials with high heat capacity and/or capable of storing latent heat, and wherein the core transmits heat to a boiler or furnace which is in contact with the HSU, either via a common interface or a pipe system circulating a hot fluid from the container to a boiler, and
(iii) an arrangement of hollow light tube concentrators that transport solar radiation directly to the HSU via the curved exit tubes and light transport method of claim 5, in which said exit tubes terminate in the form of heat diffusers within said transition zone or inside the hot core, and
(iv) a quantitative method of heat loss reduction from the HSU that adapts the properties, dimensions and structures of the transition and insulating zones to the reduction of core temperature during the work cycle, such that said zones structurally embody a counteracting and delaying dynamic response to cooling of the core, and therefore consistently reduces heat loss under all operating conditions.

19. The system of claim 1, wherein the methods provided for a concentrator based on light tubes or mirrors, further constitute a method of providing a concentrator field or panel that is lightweight, and therefore capable of being mounted on an open structure that supports a rigid or flexible framework at any height above ground which is either static or includes a tracking device, such that said method further constitutes a method for allowing dual use of the land area covered by said concentrator field, and wherein said support structure and tracking device may take a plurality of forms, including:
(i) an arch-based support structure,
(ii) a support structure based on linear elements,
(iii) a tensile suspension-based support structure that allows the concentrator field or panel to be mounted on a network of ropes,
(iv) a tensegrity-based thin-shell support structure that allows the concentrator field or panel to be mounted on a dome-structure, and
(v) in conjunction with said structures an oscillating tracking device with one or two axes that is either motor- or solar-driven.

20. The system of claim 1, wherein the methods provided for a concentrator based on light tubes or mirrors, further constitute a method of providing a concentrator field, unit or panel capable of utilizing sunlight despite being moved by waves, wherein the methods provided for protecting the concentrator within a sealed casing or container, further constitute a method for providing a concentrator field, unit or panel that is inherently buoyant and watertight, and therefore capable of being mounted on, or constituting a floating structure, such as a pontoon raft or buoyant sealed container, or being corralled within a wave breaker, and wherein said floating structure is constructed in accordance with the following methods:
(i) a method of self-stabilization based on either catamaran or outrigger pontoons or mono-hull ballast, and
(ii) a method of preventing local mechanical damage; wherein each floating unit is made able to withstand lateral mechanical damage due to contact with neighboring units by including an external, peripheral fender, and
(iii) a method of preventing global mechanical damage; wherein, depending on expected wave energy, an external barrier in the form of a wave breaker encloses the whole or part of the field, and
(iv) a method of preventing fouling by birds and salt-water; wherein the surface of each floating unit is either too steep for birds to land, or has attached spikes to the same end, and wherein the surface is made from a water-repellent, self-cleaning material, and
(v) a method of giving the concentrator field dual or triple function capability; wherein the field is capable of utilizing a floating wave-energy converter either as support structure or as global barrier, and wherein an optional fish-trapping device is provided.
